(19) United States
(12) Patent Application Publication
(10) Pub. No.: US 2015/0162383 A1
(43) Pub. Date: Jun. 11, 2015

(54) VERTICAL RESISTIVE RANDOM ACCESS MEMORY DEVICE, AND METHOD FOR MANUFACTURING SAME

(71) Applicant: Intellectual Discovery Co., Ltd., Seoul (KR)

(72) Inventor: Hyun-Sang Hwang, Daegu (KR)

(73) Assignee: INTELLECTUAL DISCOVERY CO., LTD., Seoul (KR)

(21) Appl. No.: 14/396,203

(22) PCT Filed: Jun. 25, 2013
(86) PCT No.: PCT/KR2013/005570

§ 371 Date: Oct. 22, 2014

(30) Foreign Application Priority Data
Jun. 28, 2012 (KR) 10-2012-0069608
Jun. 28, 2012 (KR) 10-2012-0069609
Jun. 28, 2012 (KR) 10-2012-0069610
Jul. 31, 2012 (KR) 10-2012-0083570
Jul. 31, 2012 (KR) 10-2012-0083571

(51) Int. Cl. H01L 27/24; H01L 45/00

(52) U.S. Cl. CPC H01L 27/2481; H01L 45/1233; H01L 45/1253; H01L 45/146; H01L 45/08; H01L 45/1608

(57) ABSTRACT

The present invention relates to a resistance change memory device and a method for manufacturing the same. According to an exemplary embodiment of the present invention, the resistance change memory device includes: a plurality of horizontal electrodes configured to be stacked at a predetermined interval from each other and extended in a horizontal direction; inter-layer insulating layers configured to each be formed between the plurality of horizontal electrodes; a plurality of vertical electrodes configured to have cross points with the horizontal electrodes by penetrating through the plurality of stacked horizontal electrodes and the inter-layer insulating layers in a vertical direction; and a metal oxide layer configured to have a U-shaped section in a form enclosing the horizontal electrode between the inter-layer insulating layer and the horizontal electrode and to make an oxygen composition ratio of a surface contacting the vertical electrode be higher than that of a surface contacting the horizontal electrode by performing oxygen treatment on the vertical electrode to have threshold switching characteristics and memory switching characteristics.

### TECHNICAL FIELD

The present invention relates to a vertically stacked resistance change RAM (ReRAM), and more particularly, to a ReRAM device and a method for manufacturing the same capable of improving integration by forming a metal oxide layer having threshold switching characteristics and memory switching characteristics at cross points at which a plurality of horizontal electrodes extending in a horizontal direction and stacked having an insulating layer therebetween and vertical electrodes extending in a vertical direction meet each other.

### BACKGROUND ART

With the development of the electronics industry, particularly the PC industry and the communications industry due to the development of an information industry, mobile devices have been developed. That is, as the PC industry and the communications industry have expanded, rapid high performance and multi-functionality surpassing existing speed of technical development have been required.

In the traditional viewpoint, for high performance and multi-functionality of a semiconductor device, a major development target of the semiconductor industry has been to implement a method for configuring various circuits within a given area. For this purpose, fineness of a manufacturing process technology has been most intensively promoted and has been sustained while satisfying Moore's law up to now. Particularly, since a flash memory device which is a nonvolatile memory which has recently come into the limelight has a difficulty in scaling, to develop a next-generation terabit nonvolatile memory, the development of a memory device based on a new characteristic material for a semiconductor device is urgently required.

In this aspect, a resistance change RAM (ReRAM) is emerging as the most promising next-generation nonvolatile memory device due to a simple process and an excellent on/off characteristic. Studies on the ReRAM are still in an initial stage of development, and therefore a difference between global technology and domestic technology is not so large. As a result, entry barriers into the ReRAM are low and thus studies for securing core technology thereof have been actively conducted.

The ReRAM generally has a structure of a metal/a metal oxide/a metal (MIM) using the metal oxide. Further, the ReRAM changes a high resistance state (HRS or off state) of the metal oxide to a low resistance state (LRS or on state) thereof, or vice versa, when an electrical signal is appropriately applied to the metal oxide, and therefore shows characteristics of a memory device. An electrical scheme for implementing on/off switching memory characteristics may be classified into a current controlled negative differential resistance (CCNR) and a voltage controlled negative differential resistance (VCNR). The VCNR shows a feature in which a current is changed from a large state to a small state with the increase in voltage, and therefore may implement memory characteristics using a large difference in resistance which appears at that time.

Many studies on the switching characteristics of the metal oxide of which the resistance state is changed in response to the applied voltage have been conducted over a long period of time, and as a result, two main switching models have been proposed.

First, one of the two switching models is a conducting filament model.

According to the conducting filament model, structural change is caused inside the metal oxide, and thus a path which has a resistance state different from the metal oxide and high conductivity is formed. According to the conducting filament model, the conducting filament having high conductivity is formed by diffusing or injecting an electrode metal material into a thin film due to an electrical stress (generally referred to as a forming process) or by rearranging a defective structure within the thin film. The conducting filament may be destroyed by Joule heating in a local area, and as a phenomenon in which the conducting filament is formed again due to factors such as a temperature inside the thin film, a temperature outside the thin film, an applied electric field, and a space charge phenomenon repeatedly occurs, the conducting filament exhibits the switching characteristics.

Second, the other of the two switching models is a switching model due to a lot of traps which are present inside the metal oxide. Generally, when a lot of traps associated with metal particles or oxygen particles which are present in the metal oxide are charged and discharged with charges, band bending occurs at an electrode and a thin film interface or a change in internal electric field occurs due to the space charge, and therefore the switching characteristics appear.

By the mechanisms, the ReRAM device shows much higher operation speed (tens of nanoseconds) than the existing flash memory, and may be operated even at a low voltage (2 to 5 V or less) like a DRAM. Further, since like an SRAM, the ReRAM device enables fast read-write operations and has a simple structure, the ReRAM device may reduce defects which may occur during the process and reduce process costs, such that the ReRAM device may be manufactured at a low cost. In addition, the ReRAM is not affected by cosmic radiation, electromagnetic waves, and the like, and therefore may demonstrate an appropriate function even in outer space, and performance thereof does not deteriorate even if write and erase are repeated 10¹⁰ times or more.

Thanks to the merits, the ReRAM device may be applied to all devices which require a storage medium, in particular, has characteristics suitable for a usage of a memory device which is a system-on-chip (SoC) type like an embedded integrated circuit (IC).

Despite the merits, an accurate switching mechanism of the ReRAM is not yet known and therefore the ReRAM has a considerable drawback in reproduction, and further has a slight deviation in operating voltage, current, durability, and the like among devices. Therefore, in order to propel commercialization of the ReRAM, universal research and development for development of a new material to solve the above-mentioned problems, investigation of a switching mechanism, process development, process equipment, circuit design, and the like is required.

Meanwhile, to improve integration of the ReRAM device, a memory device in which a plurality of horizontal electrodes which extend in a horizontal direction and a plurality of vertical electrodes which extend in a vertical direction are disposed at cross points and resistance change material layers are formed at the cross points has recently been proposed.

The ReRAM device which is disclosed in Japanese Patent Application Laid-Open No. 2011-129639 is a ReRAM device in which a plurality of horizontal electrodes which extend in a horizontal direction and a plurality of vertical electrodes which extend in a vertical direction are disposed at cross points. In the ReRAM device, rectifying insulating layers, conductive layers, and resistance variable layers are mounted in opposite areas of each electrode, in which the rectifying insulating layer is mounted to contact one side of the horizontal electrode and the vertical electrode, the resistance variable layer is mounted to contact a side in another direction of the horizontal electrode and the vertical electrode, and the conductive layer is mounted between the rectifying insulating layer and the resistance variable layer and is segmented in an area between the adjacent electrodes in a section in the horizontal electrode direction or the vertical electrode direction. The related art may improve integration by forming a ReRAM cell at the cross point between the vertical electrode and the horizontal electrode, but has a drawback in that a manufacturing process is still complicated.

Meanwhile, to implement the ReRAM device as an array, the ReRAM device exhibiting the memory characteristics and a selection device electrically connected to the ReRAM device are generally provided. The selection device may be a transistor or a diode. However, the transistor has a limitation in a size reduction of the device due to a short channel effect like a punch through. Further, the diode makes a current flow only in one direction and therefore may not be appropriate for a bipolar device exhibiting resistance change characteristics at both polarities like the ReRAM device.

Japanese Patent Application Laid-Open No. 2011-129639 uses the rectifying insulating layer as the selection device. The selection device may be a transistor or a diode. However, the selection devices proposed until now may not provide a sufficient current to operate the resistance change material layer due to a small current density. To overcome the above problem, the area of the selection device needs to be sufficiently larger than that of the resistance change material layer.

Meanwhile, generally, in the ReRAM, a current path is formed in the resistance change material layer or a current path formed therein disappears on the basis of a voltage applied between a lower electrode and an upper electrode. Generally, the current path is generated along a grain boundary. However, the current path is formed at different applied voltages, and therefore a distribution of voltage which causes a change in resistance of the resistance change material layer is expanded. That is, the ReRAM clearly has two different resistance states, but has an excessively wide range of voltage in which the two resistance states start to change. As such, when the distribution of voltage which causes the change in resistance is wide, it is difficult to reproduce the change in resistance of the resistance change material layer in a limited range of voltage. This means that the resistance change material layer needs to have the same resistance state at the same applied voltage but may not actually have it. To solve the problems, there is a need to make a contact area between the resistance change material layer associated with memory switching and an electrode small if possible.

The above information disclosed in this Background section is only for enhancement of understanding of the background of the invention and therefore it may contain information that does not form the prior art that is already known in this country to a person of ordinary skill in the art.

### DISCLOSURE

### Technical Problem

The present invention has been made in an effort to provide a vertically stacked ReRAM device having a hybrid switching layer and a method for manufacturing the same capable of improving integration and saving manufacturing costs by simplifying a manufacturing process by forming a metal oxide layer having threshold switching characteristics and memory switching characteristics at cross points at which a plurality of horizontal electrodes extending in a horizontal direction and stacked having an insulating layer therebetween and vertical electrodes extending in a vertical direction meet each other.

Further, the present invention has been made in an effort to provide a vertically stacked ReRAM device and a method for manufacturing the same capable of stable operation by making an area of a selection device sufficiently wider than that of a resistance change material layer by extending selection device function layers along vertical electrodes to be commonly used by memory cells, in a vertically stacked ReRAM in which the resistance change material layers are formed at cross points at which a plurality of horizontal electrodes extending in a horizontal direction and stacked having an insulating layer therebetween and the vertical electrodes extending in a vertical direction meet each other.

Further, the present invention has been made in an effort to provide a vertically stacked ReRAM device and a method for manufacturing the same capable of minimizing a contact area between a resistance change material layer and an electrode by forming a thin film layer between the resistance change material layer and a horizontal electrode using atomic layer deposition (ALD) to bring the resistance change material layer into contact with the horizontal electrode through a fine gap formed in the thin film layer, in a vertically stacked ReRAM in which the resistance change material layers are formed at cross points at which a plurality of horizontal electrodes extending in a horizontal direction and stacked having an insulating layer therebetween and the vertical electrodes extending in a vertical direction meet each other.

Further, the present invention has been made in an effort to provide a vertically stacked ReRAM device and a method for manufacturing the same capable of improving switching uniformity of a resistance change material layer by configuring a horizontal electrode in multi-layers using conductive materials having different etch selectivities to have a lightening rod structure, in a vertically stacked ReRAM in which resistance change material layers are formed at cross points at which a plurality of horizontal electrodes extending in a horizontal direction and stacked having an insulating layer therebetween and vertical electrodes extending in a vertical direction meet each other.

Further, the present invention has been made in an effort to provide a vertically stacked ReRAM device and a method for manufacturing the same capable of being driven without a selection device by configuring resistance change material layers, which are formed at cross points at which a plurality of horizontal electrodes extending in a horizontal direction and stacked having an insulating layer therebetween and vertical electrodes extending in a vertical direction meet each other, as a first resistance change material layer and a second resistance change material layer which are made of different materials, and forming a conducting filament by a metal material different from that of the first resistance change material layer, within the first resistance change material layer.

The objects of the present invention are not particularly limited to the foregoing objects, and instead, other objects and advantages of the present invention which are not mentioned will be apparent from the following description and clearly understood by those skilled in the art from the preferred embodiments of the present invention. Moreover, it will be easily understood that purposes, features, objects, and advantages of the present invention may be realized by measures and/or means and combinations thereof described by the appended claims.

### Technical Solution

An exemplary embodiment of the present invention provides a vertically stacked resistance change memory device, including: a plurality of horizontal electrodes configured to be stacked at a predetermined interval from each other and extended in a horizontal direction; inter-layer insulating layers configured to each be formed between the plurality of horizontal electrodes; a plurality of vertical electrodes configured to have cross points with the horizontal electrodes by penetrating through the plurality of stacked horizontal electrodes and the inter-layer insulating layers in a vertical direction; and a metal oxide layer configured to have a U-shaped section in a form enclosing the horizontal electrode between the inter-layer insulating layer and the horizontal electrode and to make an oxygen composition ratio of a surface contacting the vertical electrode be higher than that of a surface contacting the horizontal electrode to have threshold switching characteristics and memory switching characteristics by performing oxygen treatment on the vertical electrode.

Another exemplary embodiment of the present invention provides a method for manufacturing a vertically stacked resistance change memory device, including: (a) alternately stacking an inter-layer insulating layer and a sacrificial layer on a substrate; (b) forming first openings spaced from each other at a predetermined interval, while penetrating through the inter-layer insulating layer and the sacrificial layer in a vertical direction and forming pillar parts by filling the first openings with a removable material; (c) forming concave portions between the inter-layer insulating layers by forming a plurality of second openings between the pillar parts and then removing the sacrificial layer; (d) forming a metal oxide layer on the pillar part and the inter-layer insulating layer which are exposed by the concave portion; (e) forming horizontal electrodes by embedding a conductive material on the metal oxide layer formed inside the concave portion; (f) forming a third opening by removing the pillar part so as to expose a portion of the metal oxide layer; (g) performing oxygen treatment on the metal oxide layer exposed through the third opening so as to have memory switching characteristics and threshold switching characteristics; and (h) embedding a conductive material within a third opening to form vertical electrodes.

The metal oxide layer may include the same metal oxide, a surface contacting the vertical electrode may have a high oxygen composition ratio and thus have the memory switching characteristics, and a surface contacting the horizontal electrode may have the threshold switching characteristics.

The metal oxide layer may be made of any one of FeOₓ, VOₓ, TiOₓ, and NbOₓ. The horizontal electrode and the vertical electrode may be formed of a metal conductor.

The inter-layer insulating layer may be made of a silicon nitride and the sacrificial layer may be made of a silicon oxide.

Yet another exemplary embodiment of the present invention provides a resistance change memory device, including: a plurality of horizontal electrodes configured to be stacked at a predetermined interval from each other and extend in a horizontal direction; inter-layer insulating layers configured to each be formed between the plurality of horizontal electrodes; a plurality of vertical electrodes configured to have cross points with the horizontal electrodes by penetrating through the plurality of stacked horizontal electrodes and the inter-layer insulating layers in a vertical direction; a selection device function layer configured to extend in a length direction along a side wall of the vertical electrode and control a passing current amount depending on a magnitude or polarity of an applied voltage; a conductive layer configured to be formed on the inter-layer insulating layer and the selection device function layer between the inter-layer insulating layer and the horizontal electrode; and a resistance change material layer configured to be formed between the conductive layer and the horizontal electrode to have a resistance value varying in response to the applied voltage.

Yet another exemplary embodiment of the present invention provides a method for manufacturing a resistance change memory device, including: (a) alternately stacking an inter-layer insulating layer and a sacrificial layer on a substrate; (b) forming first openings spaced from each other at a predetermined interval, while penetrating through the inter-layer insulating layer and the sacrificial layer in a vertical direction; (c) depositing a selection device function layer on an inner wall of the first opening and forming vertical electrodes by filling insides of the first openings with a conductive layer; (d) forming concave portions between the inter-layer insulating layers by forming a plurality of second openings between the vertical electrodes and then removing the sacrificial layer; (e) forming a conductive layer on the selection device function layer and the inter-layer insulating layer which are exposed by the concave portion; (f) forming a resistance change material layer on the conductive layer; and (g) forming horizontal electrodes by embedding a conductive material on the resistance change material layer formed within the concave portion.

Yet another exemplary embodiment of the present invention provides a resistance change memory device, including: a plurality of horizontal electrodes configured to be stacked at a predetermined interval from each other and extend in a horizontal direction; inter-layer insulating layers configured to each be formed between the plurality of horizontal electrodes; a plurality of vertical electrodes configured to have cross points with the horizontal electrodes by penetrating through the plurality of stacked horizontal electrodes and the inter-layer insulating layers in a vertical direction; a resistance change material layer configured to extended in a length direction along a side wall of the vertical electrode to have a resistance value varying in response to an applied voltage; and a thin film layer configured to have a fine gap between the resistance change material layer and the horizontal electrode to bring the resistance change material layer into contact with the horizontal electrode through the fine gap.

Yet another exemplary embodiment of the present invention provides a method for manufacturing a resistance change memory device, including: (a) alternately stacking an inter-layer insulating layer and a conductive layer on a substrate; (b) forming a plurality of first openings spaced from each other at a predetermined interval, while penetrating through the inter-layer insulating layer and the conductive layer in a vertical direction to form horizontal electrodes; (c) forming a thin film layer having a fine gap on an inner wall of the first opening; (d) forming a resistance change material layer on the thin film layer; and (f) forming vertical electrodes by embedding the conductive layer on the resistance change material layer so as to fill the first opening.

Yet another exemplary embodiment of the present invention provides a resistance change memory device, including: a plurality of horizontal electrodes configured to be stacked at a predetermined interval from each other, extend in a horizontal direction, and have a multi-layer structure using conductive materials having different etch selectivities; inter-layer insulating layers configured to each be formed between the plurality of horizontal electrodes; a plurality of vertical electrodes configured to have cross points with the horizontal electrodes by penetrating through the plurality of stacked horizontal electrodes and the inter-layer insulating layers in a vertical direction; and a resistance change material layer configured to extend in a length direction along a side wall of the vertical electrode to have a resistance value varying in response to the applied voltage.

Yet another exemplary embodiment of the present invention provides a method for manufacturing a resistance change memory device, including: alternately stacking an inter-layer insulating layer and a conductive layer on a substrate, conductive materials of the conductive layer having different etch selectivities being stacked in a multi-layer; forming a plurality of first openings spaced from each other at a predetermined interval, while penetrating through the inter-layer insulating layer and the conductive layer in a vertical direction to form horizontal electrodes; forming a resistance change material layer on the inner wall of the first opening; and forming vertical electrodes by embedding the conductive layer on the resistance change material layer so as to fill the first opening.

Yet another exemplary embodiment of the present invention provides a method for manufacturing a resistance change memory device, including: alternately stacking an inter-layer insulating layer and a conductive layer on a substrate, conductive materials of the conductive layer having different etch selectivities being stacked in a multi-layer; forming a plurality of first openings spaced from each other at a predetermined interval, while penetrating through the inter-layer insulating layer and the conductive layer in a vertical direction to form horizontal electrodes; selectively etching the horizontal electrode exposed within the first opening; forming a resistance change material layer on an inner wall of the first opening; and forming vertical electrodes by embedding the conductive layer on the resistance change material layer so as to fill the first opening.

Yet another exemplary embodiment of the present invention provides a resistance change memory device, including: a plurality of horizontal electrodes configured to be stacked at a predetermined interval from each other and extend in a horizontal direction; inter-layer insulating layers configured to each be formed between the plurality of horizontal electrodes; a plurality of vertical electrodes configured to have cross points with the horizontal electrodes by penetrating through the plurality of stacked horizontal electrodes and the inter-layer insulating layers in a vertical direction; a first resistance change material layer configured to contact the vertical electrode between the vertical electrode and the horizontal electrode and be provided with a metal ion filament; and a second resistance change material layer configured to be made of a material different from the first resistance change material layer and formed between the horizontal electrode and the first resistance change material layer.

Yet another exemplary embodiment of the present invention provides a method for manufacturing a vertically stacked resistance change memory device, including: (a) alternately stacking an inter-layer insulating layer and a sacrificial layer on a substrate; (b) forming first openings spaced from each other at a predetermined interval, while penetrating through the inter-layer insulating layer and the sacrificial layer in a vertical direction and forming vertical electrodes within the first openings; (c) forming concave portions between the inter-layer insulating layers by forming a plurality of second openings between the vertical electrodes and then removing the sacrificial layer; (d) forming a first resistance change material layer within the concave portion; (e) forming a metal ion filament within the first resistance change material layer by heat treatment after a metal material is deposited within the concave portion on the first resistance change material layer; (f) removing the metal material within the concave portion; (g) forming a second resistance change material layer of a material different from the first resistance change material layer on the first resistance change material layer; and (h) forming horizontal electrodes by embedding a conducive material on the second resistance change material layer formed within the concave portion.

### Advantageous Effects

According to the exemplary embodiments of the present invention, it is possible to implement the resistance change memory (ReRAM) without the separate selection device merely by forming the metal oxide layers having the threshold switching characteristics and the memory switching characteristics at the cross points at which the plurality of horizontal electrodes extending in the horizontal direction and stacked having the insulating layer therebetween and the vertical electrodes extending in the vertical direction meet each other, thereby minimizing the manufacturing costs.

Further, according to the exemplary embodiments of the present invention, it is possible to further increase the integration by disposing the metal oxide layers having both of the threshold switching characteristics and the memory switching characteristics between the vertical electrodes having the plurality of horizontal electrodes stacked therebetween and penetrating between the horizontal electrodes in the vertical direction.

Further, according to the exemplary embodiments of the present invention, it is possible to provide the cell structure capable of being commonly used by memory cells by extending the selection device function layer along the vertical electrode, in the vertically stacked resistance change memory in which the resistance change material layers are formed at the cross points at which the plurality of horizontal electrodes extending in the horizontal direction and stacked having the insulating layer therebetween and the vertical electrodes extending in a vertical direction meet each other.

According to the exemplary embodiments of the present invention, it is possible to stably operate the resistance change memory by providing the sufficient current density for the resistance state change of the resistance change material layer by making the area of the selection device be sufficiently wider than that of the resistance change material layer. Further, according to the exemplary embodiments of the present invention, it is possible to minimize the contact area between the resistance change material layer and the electrode by providing the contact between the resistance change material layer and the horizontal electrode through the fine gap of the thin film layer formed between the resistance change material layer and the horizontal electrode, in the vertical resistance change memory in which the resistance change material layers are formed at the cross points at which the plurality of horizontal electrodes extending in the horizontal direction and stacked having the insulating layer therebetween and the vertical electrodes extending in a vertical direction meet each other, thereby stably operating the resistance change memory.

Further, according to the exemplary embodiments of the present invention, it is possible to improve the switching uniformity of the resistance change material layer by configuring the horizontal electrode in the multi-layer using the conductive materials having the different etch selectivities to have the lightening rod structure, in the vertical resistance change memory in which the resistance change material layers are formed at the cross points at which the plurality of horizontal electrodes extending in the horizontal direction and stacked having the insulating layer therebetween and the vertical electrodes extending in a vertical direction meet each other, thereby stably operating the resistance change memory.

Further, according to the exemplary embodiments of the present invention, it is possible to drive the ReRAM device without the selection device by configuring the resistance change material layers, which are formed at the cross points at which the plurality of horizontal electrodes extending in the horizontal direction and stacked having the insulating layer therebetween and the vertical electrodes extending in the vertical direction meet each other, as the first resistance change material layer and the second resistance change material layer which are made of different materials and forming the conducting filament by the metal material different from the first resistance change material layer, within the first resistance change material layer, thereby minimizing the manufacturing costs and improving the integration.

### DESCRIPTION OF THE DRAWINGS

FIG. 1 is a cross-sectional view of a vertically stacked resistance change memory device according to an exemplary embodiment of the present invention.

FIGS. 2 to 11 are process cross-sectional views for describing a method for manufacturing a vertically stacked resistance change memory device according to an exemplary embodiment of the present invention.

FIGS. 12 to 19 are cross-sectional views for describing a current-voltage characteristic of a resistance change memory unit cell according to an exemplary embodiment of the present invention.

FIG. 20 is a current-voltage graph of a resistance change memory unit cell according to an exemplary embodiment of the present invention.

FIG. 21 is a cross-sectional view of a vertically stacked resistance change memory device having a common selection device according to an exemplary embodiment of the present invention.

FIGS. 22 to 31 are process cross-sectional views for describing a method for manufacturing a vertically stacked resistance change memory device having a common selection device according to an exemplary embodiment of the present invention.

FIG. 32 is a cross-sectional view of the vertically stacked resistance change memory device according to the exemplary embodiment of the present invention.

FIG. 33 is an enlarged cross-sectional view of portion A of FIG. 32 according to the exemplary embodiment of the present invention.

FIGS. 34 to 40 are process cross-sectional views for describing the method for manufacturing a vertically stacked resistance change memory device according to the exemplary embodiment of the present invention.

FIG. 41 is a cross-sectional view of the vertically stacked resistance change memory device according to the exemplary embodiment of the present invention.

FIGS. 42 and 43 are enlarged cross-sectional views of portion A of FIG. 41 according to the exemplary embodiment of the present invention.

FIGS. 44 to 48 are process cross-sectional views for describing a method for manufacturing a vertically stacked resistance change memory device according to an exemplary embodiment of the present invention.

FIG. 49 is a cross-sectional view of the vertically stacked resistance change memory device according to the exemplary embodiment of the present invention.

FIGS. 50 to 61 are process cross-sectional views for describing the method for manufacturing a vertically stacked resistance change memory device according to the exemplary embodiment of the present invention.

FIGS. 62 and 63 are graphs illustrating a current-voltage characteristic of the resistance change memory device according to the exemplary embodiment of the present invention.

### MODE FOR INVENTION

The foregoing objects, features, and advantages will become more apparent from the following detailed description of preferred embodiments of the present invention with reference to accompanying drawings, which are set forth in detail hereinafter, and therefore those skilled in the art may easily practice the technical ideas of the present invention. Further, in describing the present invention, when a detailed description of a well-known technology relating to the present invention may unnecessarily make the spirit of the present invention unclear, the detailed description thereof will be omitted. Hereinafter, exemplary embodiments of the present invention will be described in detail with reference to the accompanying drawings.

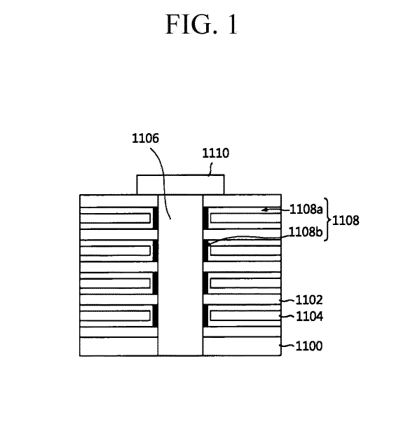

FIG. 1 is a cross-sectional view of a vertically stacked resistance change memory device according to an exemplary embodiment of the present invention. Referring to FIG. 1, insulating layers 1102 and horizontal electrodes 1104 are alternately stacked on a substrate 1100, and a plurality of vertical electrodes 1106 to vertically penetrate through the insulating layers 1102 and the horizontal electrodes 1104 are formed thereon. In this configuration, the horizontal electrode 1104 and the vertical electrode 1106 may be formed of a metal conductor, for example, Pt, Ti, TiN, TaN, and W. Further, the insulating layer 1102 may be formed of a silicon oxide layer, a silicon nitride layer, or a silicon oxynitride layer. The plurality of vertical electrodes 1106 are electrically connected to each other through bit lines 1110 which are formed thereon.

A metal oxide layer 1108 is formed between the insulating layers 1102 to have a U-shaped section so as to make one end thereof contact the vertical electrode 1106 while enclosing the horizontal electrode 1104. In this configuration, the metal oxide layer 1108 which is a non-stoichiometric layer having relatively a rich metal content may be a layer representing threshold switching characteristics. For example, the metal oxide layer 1108 may be a layer representing a metal-insulator transition, and may be FeOₓ, VOₓ, TiOₓ, or NbOₓ.

The metal oxide layer 1108 is configured to have memory switching characteristics and threshold switching characteristics by performing oxygen treatment on a portion at which the metal oxide layer 1108 contacts the vertical electrode 1106. An example of a method for performing the oxygen treatment on the portion at which the metal oxide layer 1108 contacts the vertical electrode 1106 may be a method of supplying oxygen gas to the metal oxide in a deposition equipment or exposing the exposed metal oxide to air in a state in which the metal oxide layer 1108 of a portion at which the vertical electrode is formed is exposed, prior to forming the vertical electrode 1106.

In detail, a non-exposed area in the metal oxide layer 1108 has a layer having approximately the same composition as the metal oxide layer, and may be a threshold switching layer 1108a having threshold switching characteristics. Further, an exposed area in the metal oxide layer 1108 is a layer of which the atomic ratio of metal and oxygen more approximates a stoichiometric ratio by the oxygen treatment, as compared with the threshold switching layer 1108a, and may be a memory switching layer 1108b having memory switching characteristics. Here, the memory switching layer 1108b is the same metal oxide layer as the threshold switching layer 1108a, and a composition ratio of the oxygen of the memory switching layer 1108b may be larger than that of the threshold switching layer 1108a.

The threshold switching layer 1108a may be a layer representing metal-insulator transition characteristics. The threshold switching layer 1108a may have electrical resistance that is suddenly reduced by about 10⁴ to 10⁵ times at a specific temperature (threshold temperature) or voltage (threshold voltage) or more, and thus may be transited from an insulator to a metal.

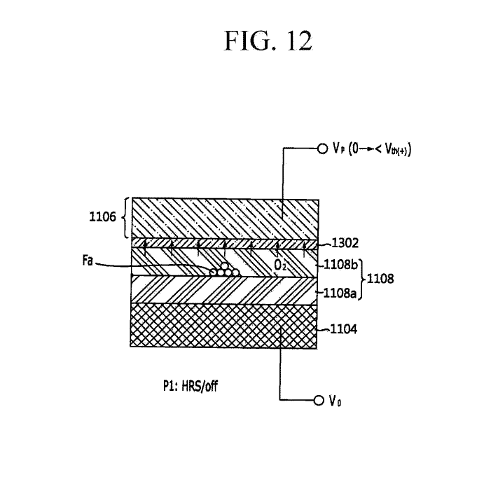

A detailed operation method of a resistance change memory using the metal oxide layer 1108 having the threshold switching layer 1108a and the memory switching layer 1108b will be described below with reference to FIGS. 12 to 14.

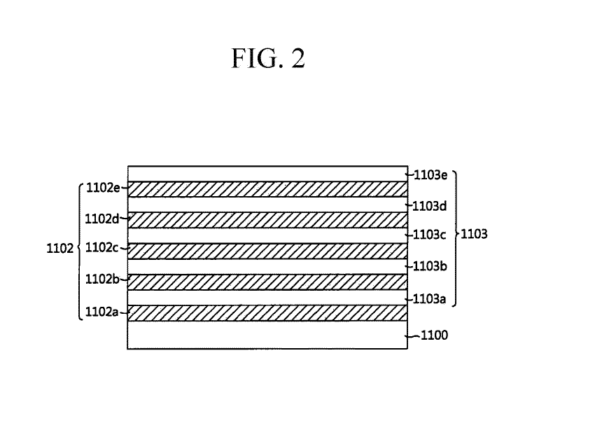

FIGS. 2 to 11 are process cross-sectional views for describing a method for manufacturing a vertically stacked resistance change memory device according to an exemplary embodiment of the present invention. To manufacture the vertically stacked resistance change memory device according to the exemplary embodiment of the present invention, first, as illustrated in FIG. 2, an inter-layer insulating layer 1102 and a sacrificial layer 1103 are repeatedly stacked on the substrate 1100 in a vertical direction. The inter-layer insulating layers 1102 and the sacrificial layers 1103 may be formed by a chemical vapor deposition process.

Although the exemplary embodiment of the present invention describes that an inter-layer insulating layer 1102a is disposed on a bottom portion of a repeatedly stacked structure and the sacrificial layer 1103e is disposed on a top portion, an inter-layer insulating layer 1102e may be disposed on the top portion.

The sacrificial layers 1103 are removed in subsequent processes and thus define portions at which the metal oxide layer is formed and the horizontal electrode is formed. The sacrificial layers 1103 and the inter-layer insulating layers 1102 need to be made of a material having etch selectivity. Further, the sacrificial layers 1103 need to be made of a material which may be easily removed by a wet etching process. Preferably, the sacrificial layers 1103 may be made of a silicon oxide and the inter-layer insulating layers 1102 may be made of a silicon nitride. Hereinafter, the case in which the sacrificial layer 1103 is formed of a silicon oxide layer and the inter-layer insulating layer 1102 is formed of a silicon nitride layer will be described.

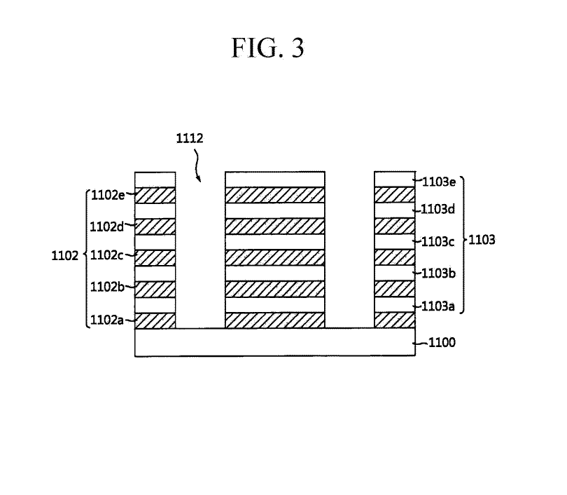

Referring to FIG. 3, a first photoresist pattern (not illustrated) is formed on a silicon oxide layer 1103e which is disposed on the top portion and first openings 1112 are formed by sequentially etching the silicon oxide layers 1103 and the silicon nitride layers 1102 using a first photoresist pattern as an etch mask. In this case, a surface of the substrate 1100 needs to be exposed on a bottom surface of the first opening 1112.

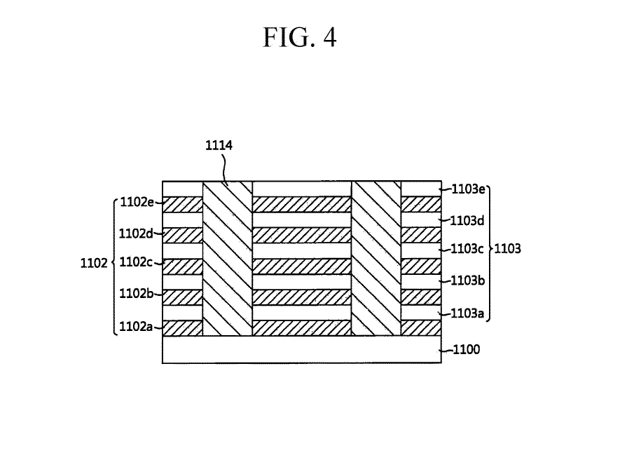

Referring to FIG. 4, insulating material patterns 1114 are formed by filling insides of the first openings 1112 with an insulating material. The insulating material pattern 1114 will be removed to form a metal oxide layer within the opening generated by removing the sacrificial layer 1103 and then form the vertical electrodes.

Therefore, the insulating material pattern 1114 is not necessarily filled with the insulating material and may be filled with any material which may be easily removed by subsequent etching.

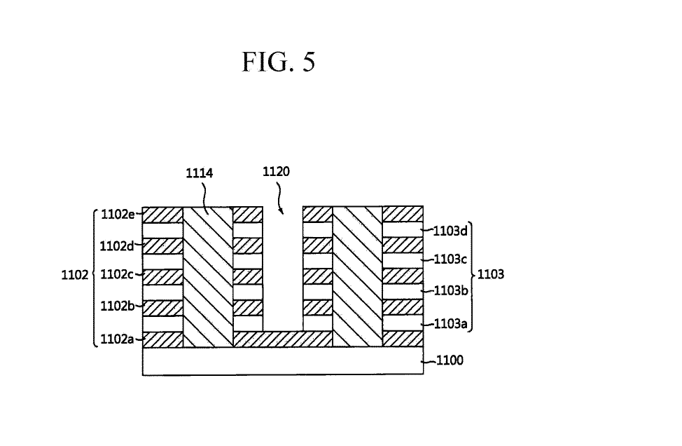

Referring to FIG. 5, after the insulating material pattern 1114 is formed within the first opening 1112, the silicon oxide layer 1103e is removed by a polishing process so as to expose the silicon nitride layer 1102e. Further, a second photoresist pattern (not illustrated) which selectively exposes a portion of the stacked structure between the insulating material patterns 114 is formed on the stacked structure. In addition, second openings 1120 are formed by etching the stacked structure using the second photoresist pattern as the etch mask. An upper surface of a first silicon nitride layer 1102a which is a bottom layer of the stacked structure needs to be exposed on a bottom surface of each second opening 1120. In this case, the second openings 1120 are provided to prepare a space in which a wet etchant is permeated into the silicon oxide layers of each layer so as to remove silicon oxide layer patterns 1103a to 1103d.

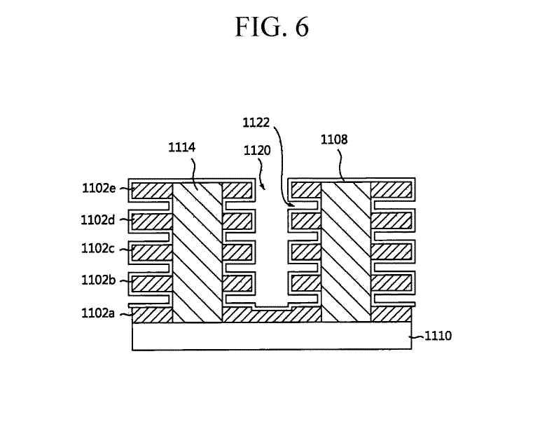

Referring to FIG. 6, the first to fourth silicon oxide layer patterns 1103a to 1103d which are exposed on side walls of the second openings 1120 are selectively removed. In this case, the first to fourth silicon oxide layer patterns 1103a to 1103d are removed by the wet etching process. In detail, the first to fourth silicon oxide layer patterns 1103a to 1103d may be removed using a hydrofluoric acid aqueous solution. When the above process is performed, the first to fifth silicon nitride layer patterns 1102a to 1102e remain on the side walls of the insulating material patterns 1114 at a predetermined interval. Further, concave portions 1122 are generated at a portion at which the first to fourth silicon oxide layer patterns 1103a to 1103d are removed from the side walls of the second openings 1120. In this case, the concave portions 11220 of each layer communicate with each other, and one side wall of the insulating material pattern 1114 is exposed by the concave portion 1122. The portion of the insulating material pattern 1114 exposed by the concave portion 1122 is a portion at which the metal oxide layer and the horizontal electrode are formed.

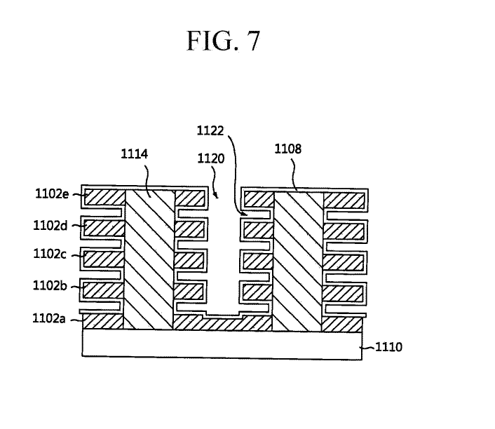

Referring to FIG. 7, the metal oxide layers 1108 are formed on the insulating material patterns 1114 and the first to fifth silicon nitride layer patterns 1102a to 1102e which are exposed by the concave portions 1122. The metal oxide layer 1108 which is a non-stoichiometric layer having a relatively rich metal content may be the layer representing the threshold switching characteristics. For example, the metal oxide layer 1108 may be the layer representing the metal-insulator transition, and may be FeOₓ, VOₓ, TiOₓ, or NbOₓ. The metal oxide layer 1108 may be formed by using a physical vapor deposition method or a chemical vapor deposition method. For example, the metal oxide layer 1108 may be formed by a sputtering method, in detail, a reactive sputtering method.

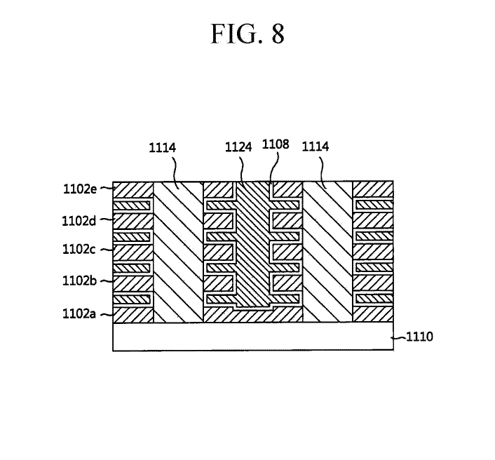

Referring to FIG. 8, a conductive layer 1124 is deposited on the metal oxide layer 1108 to completely fill the insides of the second opening 1120 and the concave portion 1122. The conductive layer 1124 is provided as a horizontal electrode pattern by subsequent processes. To fill the insides of the second opening 1120 and the concave portion 1122 with the conductive material without a void, it is preferable to perform deposition using a material having good step coverage characteristics. For example, the conductive layer 1124 may be made of Pt, Ti, TiN, TaN, W, etc.

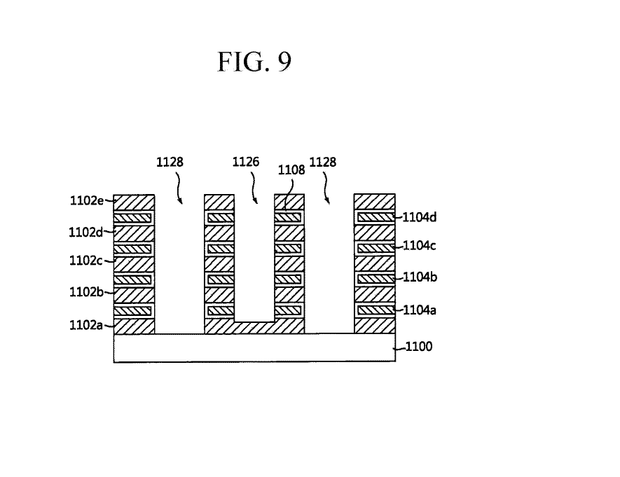

Referring to FIG. 9, a third photoresist pattern (not illustrated) is formed on an upper surface of the stacked structure to selectively expose an upper surface of the conductive layer 1124 and the insulating material pattern 1114 which are formed inside the second opening 1120. That is, the third photoresist pattern has a shape in which the same portion as the second opening 1120 or a portion wider than the second opening 1120 is exposed. Further, the conductive layer 1124 and the insulating material pattern 1114 which are exposed by using the third photoresist pattern as the etch mask undergo anisotropic etching. By this, a fourth opening 1128 partially exposing a surface of the metal oxide layer 1108 by removing the insulating material pattern 1114 while simultaneously forming a third opening 1126 which allows the conductive layer patterns 1104a to 1104d of each layer to be separated from each other in a vertical direction may be formed. The first silicon nitride layer pattern 1102a may be exposed on a bottom surface of the third opening 1126, and the substrate 1100 may be exposed on a bottom surface of the fourth opening 1128.

First to fourth layer horizontal electrode patterns 1104a to 1104e and the metal oxide layer 1108 pattern are formed between the first to fifth silicon nitride layer patterns 1102a to 1102e by the etch process. In this case, the horizontal electrode patterns 1102a to 1102e which are formed on the same layer are electrically connected to each other. However, the horizontal electrode patterns 1102a to 1102e which are formed on different layers are insulated from each other.

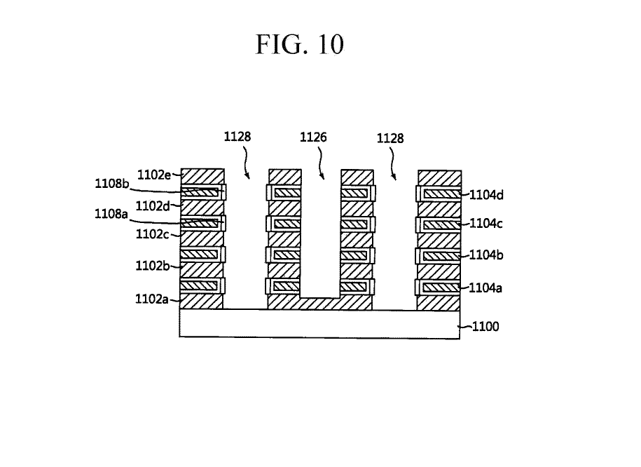

Referring to FIG. 10, the surface of the metal oxide layer 1108 which is exposed by the fourth opening 1128 undergoes the oxygen treatment. One example of performing the oxygen treatment on the surface of the metal oxide layer 1108 may be supplying oxygen gas to the metal oxide layer 1108 in a deposition equipment. As another example, the stacked structure in which the metal oxide layer 1108 is formed may be exposed to air. As the result, a hybrid switching layer having both the threshold switching characteristics and the memory switching characteristics may be formed.

In detail, the non-exposed area in the metal oxide layer 1108 has the layer having approximately the same composition as the metal oxide layer, and may be the threshold switching layer 1108a having the threshold switching characteristics. Further, the exposed area in the metal oxide layer 1108 is the layer of which the atomic ratio of metal and oxygen more approximates the stoichiometric ratio by the oxygen treatment, as compared with the threshold switching layer 1108a, and may be the memory switching layer 1108b having the memory switching characteristics. Here, the memory switching layer 1108b is the same metal oxide layer as the threshold switching layer 1108a, and the composition ratio of the oxygen of the memory switching layer 1108b may be larger than that of the threshold switching layer 1108a.

The threshold switching layer 1108a may be the layer representing the metal-insulator transition characteristics. The threshold switching layer 1108a may have electrical resistance that is suddenly reduced by about 10⁴ to 10⁵ times at a specific temperature (threshold temperature) or voltage (threshold voltage) or more, and thus may be transited from an insulator to a metal.

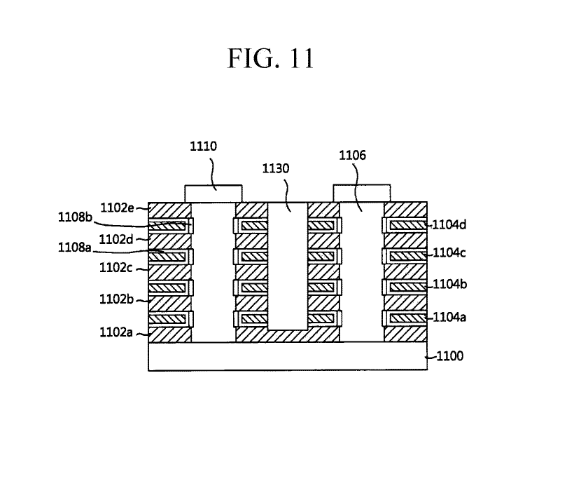

Referring to FIG. 11, after the metal oxide layer is oxidized, the vertical electrode 1106 is formed by filling an inside of the fourth opening with the conductive layer for the vertical electrode. Here, the conductive layer may be made of Pt, Ti, TiN, TaN, W, etc. Further, an insulating layer 1130 is formed to be embed inside of the third opening 1126. The insulating layer 1130 may be formed by depositing the silicon oxide using the chemical vapor deposition method. Further, the conductive layer (not illustrated) is formed on the vertical electrode patterns 1106 and the fifth silicon nitride layer patterns 1102e. Next, bit lines 1110 through which the upper portions of the vertical electrode patterns 1106 are connected to each other are formed by patterning the conductive layer using a photolithography process.

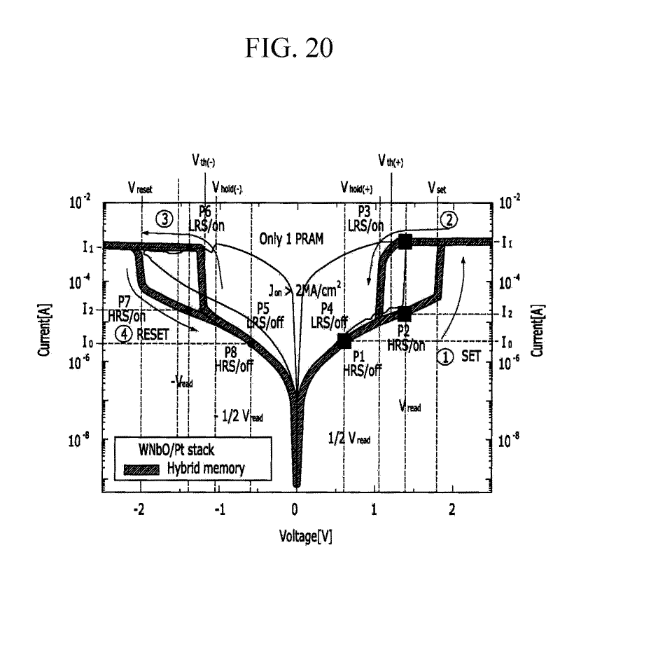

FIGS. 12 to 19 are cross-sectional views for describing a current-voltage characteristic of a resistance change memory unit cell according to an exemplary embodiment of the present invention, and FIG. 20 is a current-voltage graph of a resistance change memory unit cell according to an exemplary embodiment of the present invention.

Referring to FIGS. 12 and 20, a positive sweep voltage Vp from 0 V to less than a first threshold voltage Vth (+) is applied (P1) to the vertical electrode 1106 in a state in which a reference voltage, for example, a ground voltage V₀, is applied to the horizontal electrode 1104. In this case, oxygen ions within the memory switching layer 1108b move into the vertical electrode 1106 due to a positive electric field applied between the horizontal and vertical electrodes 1104 and 1106 to oxidize a lower area of the vertical electrode 1106, thereby increasing a thickness of a conductive oxide area 1302. At the same time, an oxygen vacancy introduced into the memory switching layer 1108b may grow an oxygen vacancy filament Fa. However, the oxygen vacancy filament Fa does not grow enough to contact the vertical electrode 1106. As the result, the memory switching layer 1108b maintains a high resistance state (HRS). Meanwhile, an effective amount of electric field is not applied to the threshold switching layer 1108a, and therefore the threshold switching layer 1108a maintains an off state (P1 state: HRS/OFF).

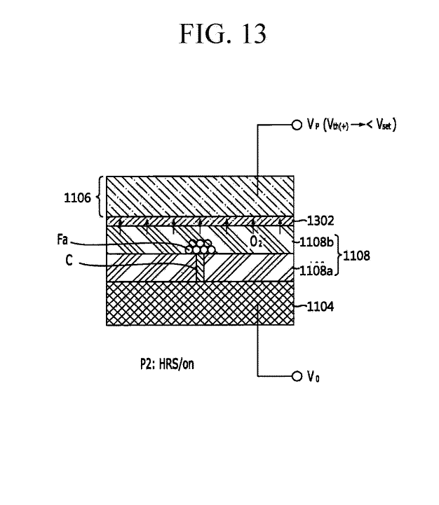

Referring to FIGS. 13 and 20, the positive sweep voltage Vp from the first threshold voltage Vth (+) to less than a set voltage Vset is applied to the vertical electrode 1106 (P2). When the first threshold voltage Vth (+) is applied to the vertical electrode 1106, the resistance of the threshold switching layer 1108a is largely reduced and thus the threshold switching layer 1108a is changed to an on state. Although a conducting filament C is illustrated in the drawings, this is not actually generated but is only suggestive that the threshold switching layer 1108a is changed to the on state. In this case, the oxygen ions within the memory switching layer 1108b move in a direction of the vertical electrode 1106 to be able to increase the thickness of the conductive oxide area 1302. At the same time, the oxygen vacancy introduced into the memory switching layer 1108b may grow the oxygen vacancy filament Fa but the oxygen vacancy filament Fa does not grow enough to contact the vertical electrode 1106. As the result, the memory switching layer 1108b maintains the high resistance state (DELETEDTEXTS (P2 state: HRS/ON).

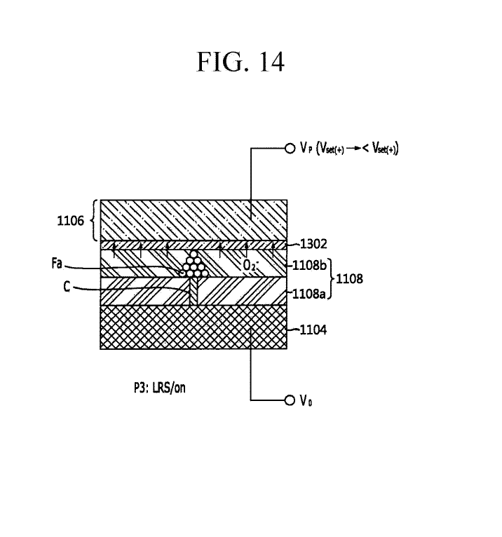

Referring to FIGS. 14 and 20, the positive sweep voltage Vp from the set voltage Vset to less than a first hold voltage Vhold (+) is applied to the vertical electrode 1106 (P3). The oxygen vacancy filament Fa contacts the vertical electrode 1106, and thus the memory switching layer 1108b is switched to a low resistance state (LRS) due to the oxygen vacancy continuously accumulated within the memory switching layer 1108b. After that, the memory switching layer 1108b maintains the low resistance state (LRS). Meanwhile, the threshold switching layer 1108a maintains an on state (P3 state: LRS/ON).

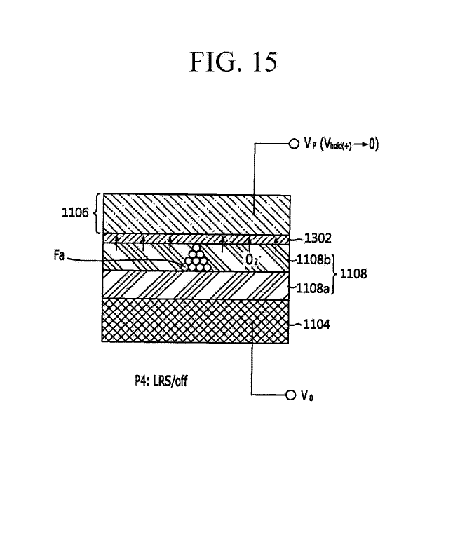

Referring to FIGS. 15 and 20, the positive sweep voltage Vp from the first hold voltage Vhold (+) to 0 V is applied to the vertical electrode 1106 (P4). When the first hold voltage Vhold (+) is applied to the vertical electrode 1106, the resistance of the threshold switching layer 1108a is largely increased and thus the threshold switching layer 1108a is changed to an off state. Meanwhile, the oxygen vacancy filament Fa maintains (P4 state: LRS/OFF) the low resistance state (LRS) to contact the vertical electrode 1106 due to the oxygen vacancy accumulated within the memory switching layer 1108b.

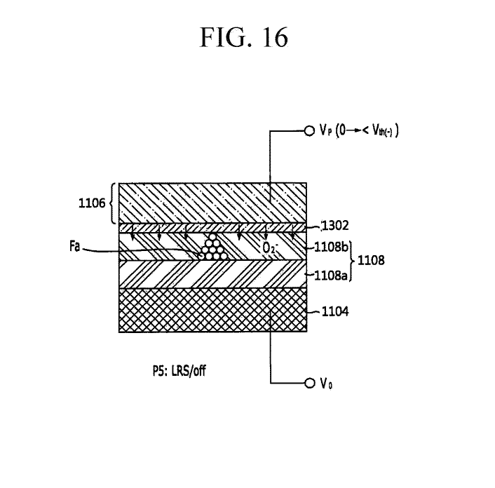

Referring to FIGS. 16 and 20, a negative sweep voltage Vm from 0 V to less than a second threshold voltage Vth (−) (based on an absolute value) is applied to the vertical electrode 1106 (P5). In this case, the oxygen ions are introduced from the vertical electrode 1106 into the memory switching layer 1108b due to a negative electric field applied between the horizontal electrodes and the vertical electrodes 1104 and 1106, but since an effective negative electric field is not applied, the oxygen vacancy filament Fa may be maintained without being separated from the vertical electrode 1106. As the result, the memory switching layer 1108b maintains the low resistance state (LRS). Meanwhile, the effective negative electric field is not applied to the threshold switching layer 1108a, and therefore the threshold switching layer 1108a maintains the off state (P5 state: LRS/OFF).

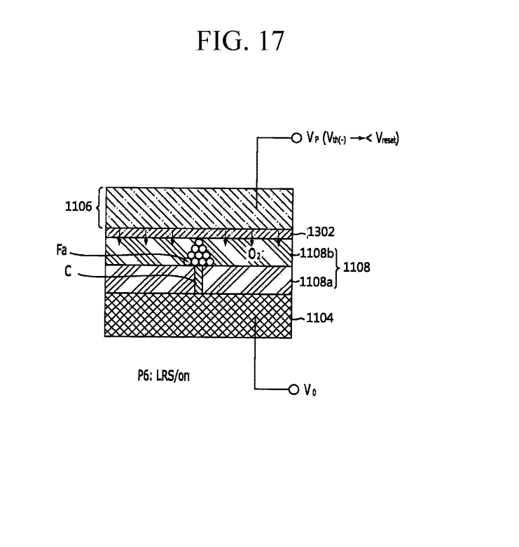

Referring to FIGS. 17 and 20, the negative sweep voltage Vm from a second threshold voltage Vth (−) to less than a reset voltage (Vreset) (based on an absolute value) is applied to the vertical electrode 1106 (P6). When the second threshold voltage Vth (−) is applied to the vertical electrode 1106, the resistance of the threshold switching layer 1108a is largely reduced and thus the threshold switching layer 1108a is changed to an on state. Although the conducting filament C is illustrated in the drawings, this is not actually generated, but is only suggestive of the threshold switching layer 1108a being changed to the on state. Meanwhile, the oxygen ions are continuously introduced from the vertical electrode 1106 into the memory switching layer 1108b due to the negative electric field applied between the horizontal electrodes and the vertical electrodes 1104 and 1106, but since the effective negative electric field is not applied, the oxygen vacancy filament Fa may be maintained without being separated from the vertical electrode 1106. As the result, the memory switching layer 1108b maintains the low resistance state (LRS) (P6 state: LRS/ON).

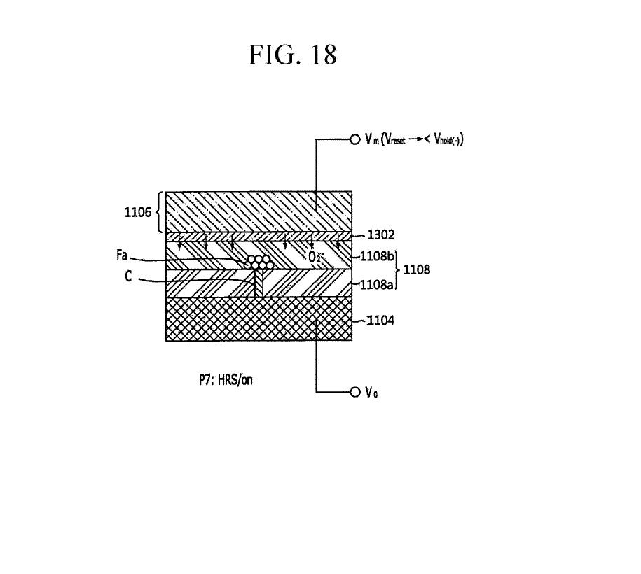

Referring to FIGS. 18 and 20, the negative sweep voltage Vm from the reset voltage Vreset to less than the second hold voltage Vhold (−) (based on an absolute value) is applied to the vertical electrode 1106 (P7). When the reset voltage Vreset is applied to the vertical electrode 1106, an end of the oxygen vacancy filament Fa within the memory switching layer 1108b is completely oxidized and is thus separated from the vertical electrode 1106. Therefore, the memory switching layer 1108b is switched to the high resistance state (HRS) and then maintains the HRS. Meanwhile, the threshold switching layer 1108a maintains the on state (P7 state: HRS/ON).

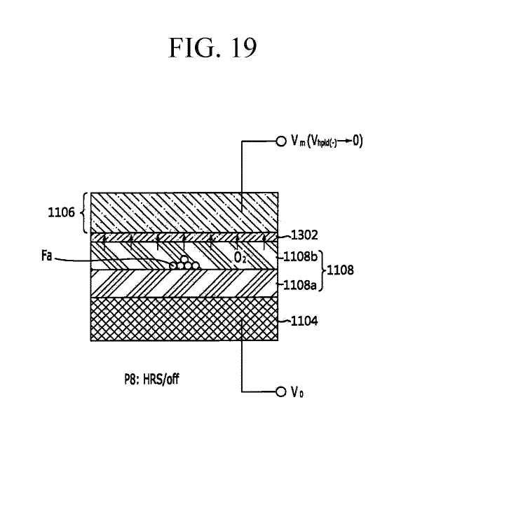

Referring to FIGS. 19 and 20, the negative sweep voltage Vm from the second hold voltage Vhold (−) to 0 V is applied to the vertical electrode 1106 (P8). When the second hold voltage Vhold (−) is applied to the vertical electrode 1106, the resistance of the threshold switching layer 1108a is largely increased and thus the threshold switching layer 1108a is changed to an off state. Meanwhile, oxygen ions are continuously introduced into the memory switching layer 1108b and therefore the oxygen vacancy filament Fa within the memory switching layer 1108b is continuously oxidized. As the result, the memory switching layer 1108b maintains the high resistance state (HRS) (P8 state: HRS/OFF).

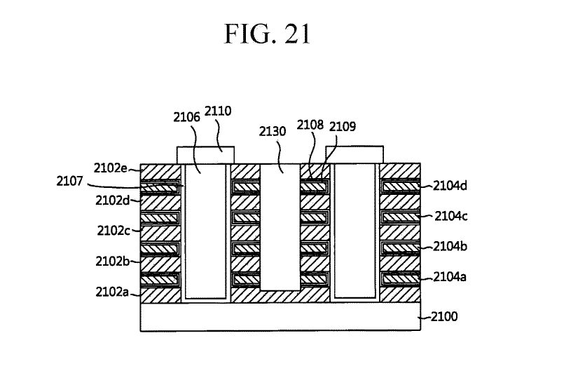

FIG. 21 is a cross-sectional view of the vertically stacked resistance change memory device having a common selection device according to an exemplary embodiment of the present invention.

Referring to FIG. 21, inter-layer insulating layers 2102a to 2102e and horizontal electrodes 2104a to 2014d are alternately stacked on a substrate 2100, and a plurality of vertical electrodes 2106 are formed to vertically penetrate through the inter-layer insulating layers 2102a to 2102e and the horizontal electrodes 2104a to 2014d. In this configuration, the horizontal electrodes 2104a to 2104d and the vertical electrodes 2106 may be formed of a metal conductor, for example, Pt, Ti, TiN, TaN, and W. Further, an inter-layer insulating layer 2102 may be formed of a silicon oxide layer, a silicon nitride layer, or a silicon oxynitride layer.

A selection device function layer 2107 is formed in a cup shape to contact the vertical electrode 2106 along an inner wall of an opening in which the vertical electrode 2106 is formed. Therefore, memory cells configured of resistance change material layers formed to contact the horizontal electrodes commonly use the selection device function layers 2107 which extend along a length direction of the vertical electrodes 2106. The selection device function layer 2107 is made of an insulating material controlling a passing current amount depending on a magnitude or polarity of a supplied voltage, and for example, may be a silicon nitride or a high dielectric insulating material such as alumina, or a metal oxide such as TaOₓ and TiOₓ. In particular, when the selection device function layer 2107 is configured of a multi-layer using an oxide layer of different materials such as TaOₓ/TiOₓ/TaOₓ, a current control graph having a large slope may be obtained. Herein, according to the exemplary embodiment of the present invention, since the silicon oxide layer is used as the sacrificial layer in the manufacturing process, the silicon oxide layer may preferably not be used as the selection device function layer 2107. Further, when the insulating layer made of a material having a large difference in a dielectric constant is stacked in a multi-layer, the selection device function layer 2107 may show a larger effect.

At a portion at which the horizontal electrodes 2104a to 2104d are formed between the inter-layer insulating layers 2102a to 2102e, conductive layers 2108 in a U-shape are formed on the inter-layer insulating layer and the selection device function layer 2107, respectively. The conductive layer 2108 may be made of a metal, a silicide, an oxide, a nitride, an impurity doped silicon, or the like, as a material having conductivity, and according to the exemplary embodiment of the present invention, a metal material may be used as the conductive layer.

A resistance change material layer 2109 is formed on the conductive layer 2108 in the U-shape like the shape of the conductive layer 2108. The resistance change material layer 2109 may be made of a transition metal oxide, a phase change material, a perovskite material, and the like as a material in which the low resistance state and the high resistance state may be repeatedly changed depending on the applied voltage. According to the exemplary embodiment of the present invention, the resistance change material layer may be an oxygen ion mobile type or a metal ion mobile type which is operated at a low switching voltage.

The plurality of vertical electrodes 2106 are electrically connected to each other through bit lines 2110 which are formed thereon. Further, in the drawings, reference numeral 2130 represents a separating insulating layer which is formed by filling an opening formed to remove the sacrificial layer with the insulating material in the manufacturing process.

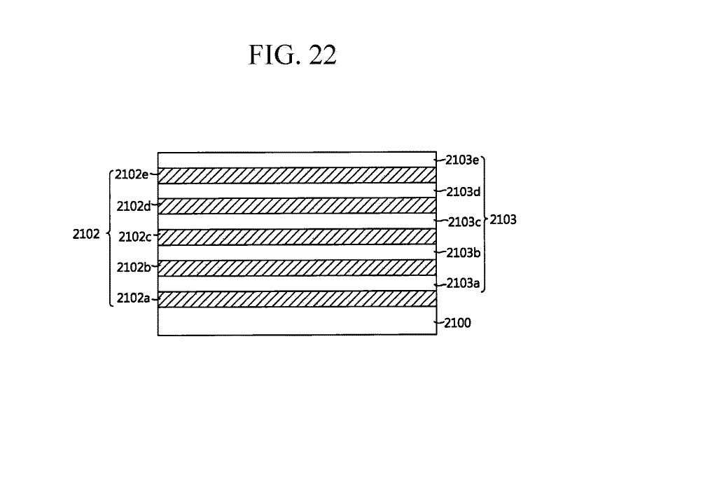

FIGS. 22 to 31 are process cross-sectional views for describing a method for manufacturing a vertically stacked resistance change memory device having a common selection device according to an exemplary embodiment of the present invention. To manufacture the vertically stacked resistance change memory device according to the exemplary embodiment of the present invention, first, as illustrated in FIG. 22, an inter-layer insulating layer 2102 and a sacrificial layer 2103 are repeatedly stacked on the substrate 2100 in a vertical direction. The inter-layer insulating layers 2102 and the sacrificial layers 2103 may be formed by the chemical vapor deposition process.

The exemplary embodiment of the present invention describes that the inter-layer insulating layer 2102a is disposed on a bottom portion of the repeatedly stacked structure and the sacrificial layer 2103e is disposed on a top portion thereof.

The sacrificial layers 2103 are removed in subsequent processes to define a portion at which the conductive layer 2108, the resistance change material layer 2109, and the horizontal electrode 2104 are formed. The sacrificial layers 2103 and the inter-layer insulating layers 2102 need to be made of a material having etch selectivity. Further, the sacrificial layers 2103 need to be made of a material which may be easily removed by the wet etching process. The sacrificial layers 2103 may be made of a silicon oxide and the inter-layer insulating layers 2102 may be made of a silicon nitride. Hereinafter, the case in which the sacrificial layer 2103 is made of the silicon oxide layer and the inter-layer insulating layer 2102 is formed of the silicon nitride layer will be described.

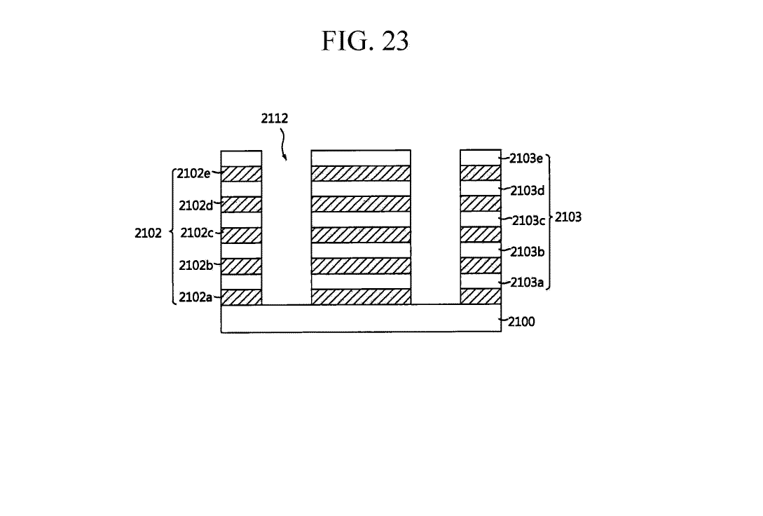

Referring to FIG. 23, the first photoresist pattern (not illustrated) is formed on a silicon oxide layer 2103e which is disposed on the top portion and first openings 2112 are formed by sequentially etching the silicon oxide layers 2103 and the silicon nitride layers 2102 using the first photoresist pattern as an etch mask. In this case, a surface of the substrate 2100 needs to be exposed on a bottom surface of the first opening 2112.

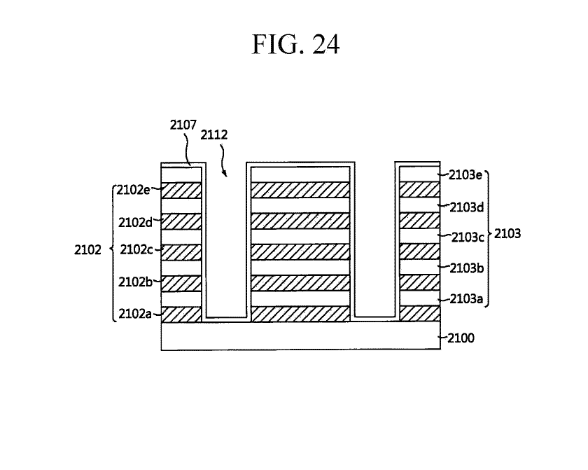

Referring to FIG. 24, the selection device function layer 2107 is deposited on the silicon oxide layer 2103e which is disposed on the top portion and along inner walls of the first openings 2112. The selection device function layer 2107 may be formed of an insulating material having a high dielectric constant by chemical vapor deposition.

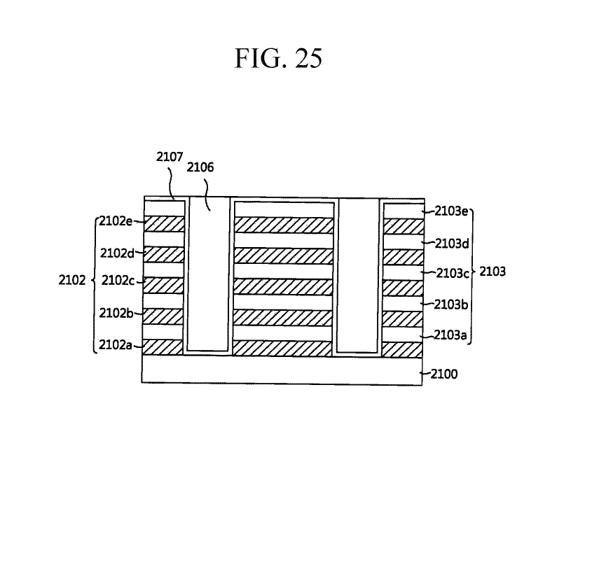

Referring to FIG. 25, the first opening 2112 is filled with the conductive material for the vertical electrode. To fill the inside of the first opening 2112 with the conductive material without a void, it is preferable to perform deposition using a material having good step coverage characteristics. For example, the conductive material may be Pt, Ti, TiN, TaN, W, etc.

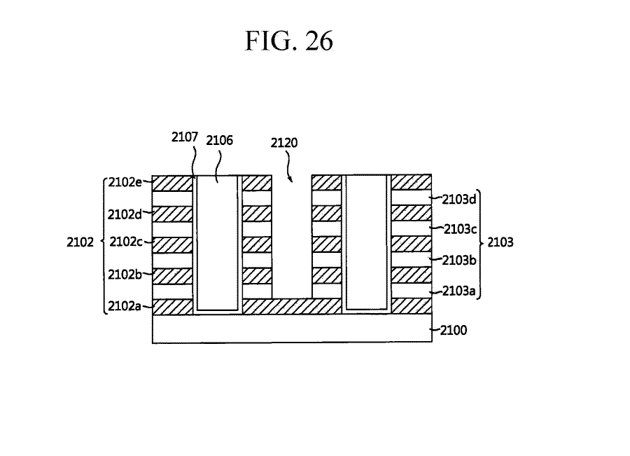

Referring to FIG. 26, after the vertical electrode 2106 is formed by filling the inside of the first opening 2112 with the conductive material, the silicon oxide layer 2103e is removed by a polishing process so as to expose the silicon nitride layer 2102e. Further, a second photoresist pattern (not illustrated) which selectively exposes a portion of the stacked structure between the vertical electrodes 2106 is formed on the stacked structure. In addition, second openings 2120 are formed by etching the stacked structure using the second photoresist pattern as the etch mask. An upper surface of the first silicon nitride layer 2102a which is a bottom layer of the stacked structure needs to be exposed on bottom surfaces of each of the second openings 2120. In this case, the second openings 2120 are provided to prepare a space in which a wet etchant is permeated into the silicon oxide layers of each layer so as to remove the silicon oxide layer patterns 2103a to 2103d.

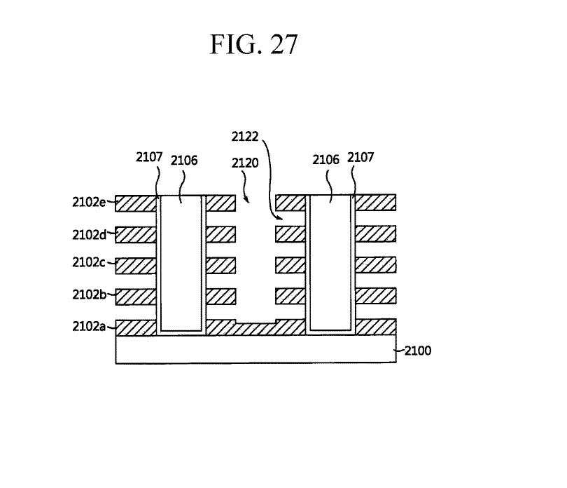

Referring to FIG. 27, first to fourth silicon oxide layer patterns 2103a to 2103d which are exposed on side walls of the second openings 2120 are selectively removed. The first to fourth silicon oxide layer patterns 2103a to 2103d are removed by the wet etching process. In detail, the first to fourth silicon oxide layer patterns 2103a to 2103d are removed using a hydrofluoric acid aqueous solution. When the process is performed, the side wall of the selection device function layer 2107 which extends in a vertical direction along the vertical electrode 2106 is still provided with the first to fifth silicon nitride layer patterns 2102a to 2102e at predetermined intervals. Further, concave portions 2122 are generated at a portion at which the first to fourth silicon oxide layer patterns 2103a to 2103d are removed from the side walls of the second openings 2120. In this case, the concave portions 2122 of each layer communicate with each other, and one side wall of the of the selection device function layer 2107 is exposed by the concave portion 2122. A portion of the selection device function layer 2107 which is exposed by the concave portion 2122 is a portion at which the conductive layer 2108, the resistance change material layer 2109, and the horizontal electrode 2104 are sequentially formed.

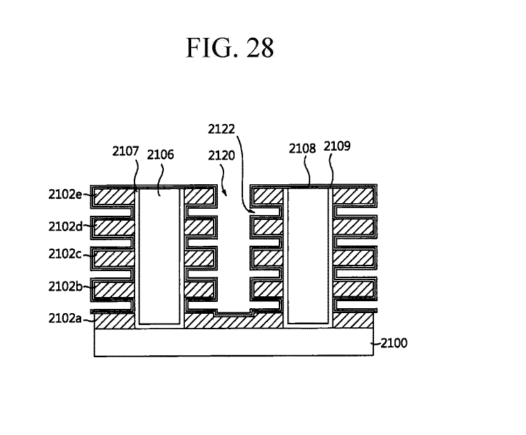

Referring to FIG. 28, the conductive layers 2108 are formed on the selection device function layer 2107 and the first to fifth silicon nitride layer patterns 2102a to 2102e which are exposed by the concave portions 2122. When the conductive 2108 is made of a conductive material, the conductive layer may be preferably made of a metal. The conductive layer 2108 may be formed by physical vapor deposition or chemical vapor deposition. For example, the conductive layer 2108 may be formed by the sputtering method, in detail, the reactive sputtering method.

Further, referring to FIG. 28, the resistance change material layer 2109 is formed on the conductive layer 2108. The resistance change material layer 2109 may be made of the transition metal oxide, the phase change material, the perovskite material, and the like as the material in which the low resistance state and the high resistance state may be repeatedly changed depending on the applied voltage. According to the exemplary embodiment of the present invention, the resistance change material layer 2109 may be an oxygen ion mobile type or a metal ion mobile type which is operated at the low switching voltage. The resistance change material layer 2109 may be deposited by the physical vapor deposition or the chemical vapor deposition. For example, the resistance change material layer 2109 may be deposited by the sputtering method, in detail, the reactive sputtering method.

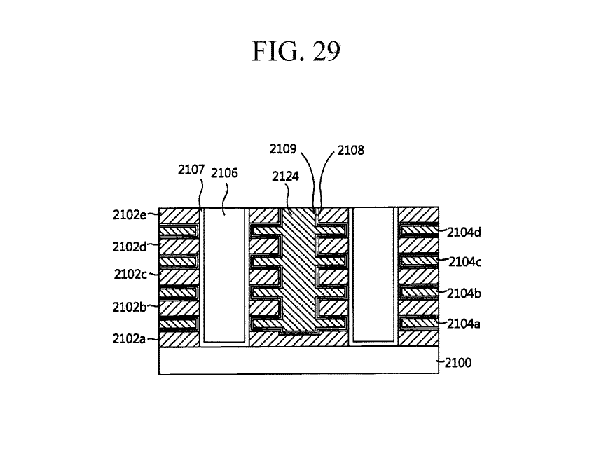

Referring to FIG. 29, a conductive layer 2124 is deposited on the resistance change material layer 2109 to completely fill the insides of the second openings 2120 and the concave portions 2122. The conductive layer 2124 is provided as the horizontal electrode pattern by subsequent processes. To fill the insides of the second opening 2120 and the concave portion 2122 with the conductive material without a void, it is preferable to perform deposition using a material having good step coverage characteristics. For example, the conductive layer 2124 may be made of Pt, Ti, TiN, TaN, W, etc.

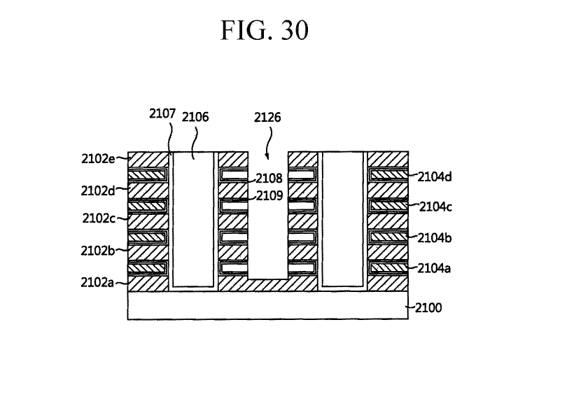

Referring to FIG. 30, a third photoresist pattern (not illustrated) which selectively exposes an upper surface of the conductive layer 2124 which is formed inside the second opening 2120 is formed on an upper surface of the stacked structure. That is, the third photoresist pattern has a shape in which the same portion as the second opening 2120 or a portion wider than the second opening 2120 is exposed. Further, the conductive layer 2124 exposed using the third photoresist pattern as the etch mask undergoes the anisotropic etching to form third openings 2126 through which the conductive layer patterns 2104a to 2104d of each layer are separated from each other in the vertical direction. The first silicon nitride layer pattern 2102a may be exposed on a bottom surface of the third opening 2126.

By the etch process, first to fourth layer horizontal electrode patterns 2104a to 2104e, the resistance change material layer 2109, and the conductive layer 2108 patterns are formed between the first to fifth silicon nitride layer patterns 2102a to 2102e. In this case, the horizontal electrode patterns 2102a to 2102e which are formed on the same layer are electrically connected to each other. However, the horizontal electrode patterns 2102a to 2102e which are formed on different layers are insulated from each other.

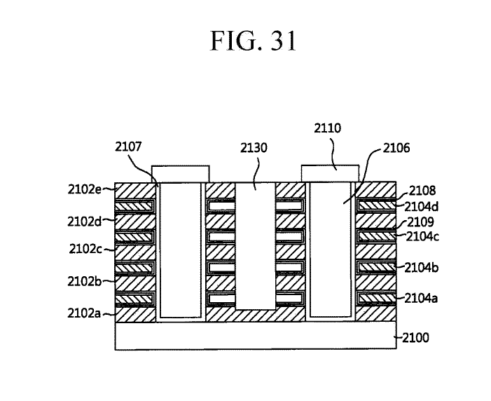

Referring to FIG. 31, the insulating layer 2130 is formed to be embedded inside of the third opening 2126. The insulating layer 2130 may be formed by depositing the silicon oxide using chemical vapor deposition. Further, the conductive layer (not illustrated) is formed on the vertical electrode patterns 2106 and the fifth silicon nitride layer pattern 2102e. Next, the bit lines 2110 through which the upper portions of the vertical electrode patterns 2106 are connected to each other are formed by patterning the conductive layer using the photolithography process.

As described above, according to the exemplary embodiments of the present invention, it is possible to provide the cell structure capable of being commonly used by memory cells by extending the selection device function layer along the vertical electrode, in the vertical resistance change memory in which the resistance change material layers are formed at the cross points at which the plurality of horizontal electrodes extending in the horizontal direction and stacked having the insulating layer therebetween and the vertical electrodes extending in a vertical direction meet each other. According to the exemplary embodiments of the present invention, it is possible to stably operate the resistance change memory by providing the sufficient current density for the resistance state change of the resistance change material layer by making the area of the selection device be sufficiently wider than that of the resistance change material layer.

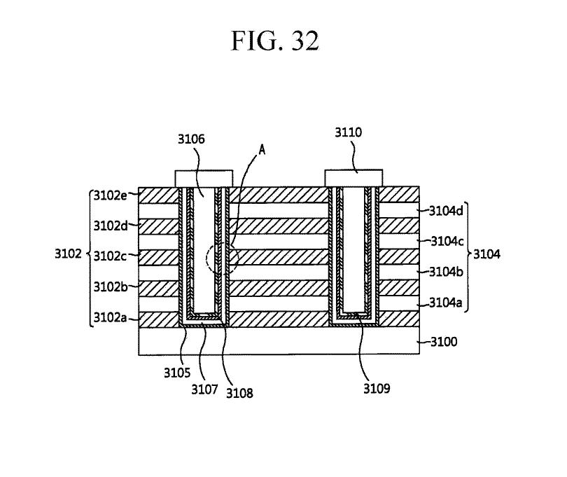

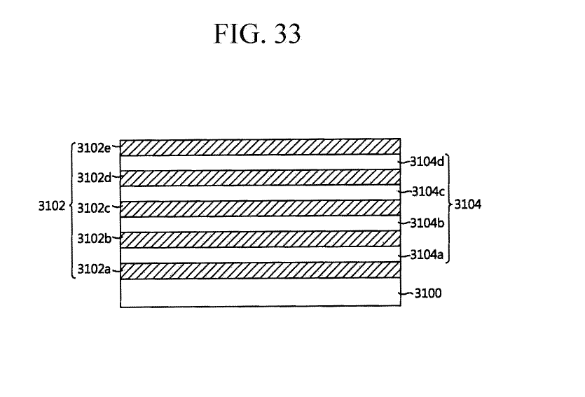

FIG. 32 is a cross-sectional view of the vertically stacked resistance change memory device according to the exemplary embodiment of the present invention, and FIG. 33 is an enlarged cross-sectional view of a portion A of FIG. 1 according to the exemplary embodiment of the present invention.

Referring to FIG. 32, inter-layer insulating layers 3102a to 3102e and horizontal electrodes 3104a to 3014d are alternately stacked on a substrate 3100, and a plurality of vertical electrodes 3106 are formed to vertically penetrate through the inter-layer insulating layers 3102a to 3102e and the horizontal electrodes 3104a to 3014d. In this configuration, the horizontal electrodes 3104a to 3104d and the vertical electrodes 3106 may be made of a metal conductor, for example, Pt, Ti, TiN, TaN, or W. Further, the inter-layer insulating layer 3102 may be formed of the silicon oxide layer, the silicon nitride layer, or the silicon oxynitride layer.

A thin film layer 3105 is formed in a cup shape to contact the inter-layer insulating layers 3102a to 3102e and the horizontal electrodes 3104a to 3104d along an inner wall of an opening in which the vertical electrode 3106 is formed. The thin film layer 3105 may be formed of the silicon oxide layer, the silicon nitride layer, or the silicon oxynitride layer as an insulating layer of 5 monolayers or less formed by the atomic layer deposition (ALD). Therefore, the thin film layer 3105 has a fine gap like B illustrated in FIG. 33.

A resistance change material layer 3107 is formed on the thin film layer 3105 and is formed in a cup shape like the thin film layer 3105. The resistance change material layer 3107 may be made of a transition metal oxide, a phase change material, a perovskite material, and the like as a material in which the low resistance state and the high resistance state may be repeatedly changed depending on the applied voltage. According to the exemplary embodiment of the present invention, the resistance change material layer 3107 may be the oxygen ion mobile type or the metal ion mobile type which is operated at the low switching voltage.

A conductive layer 3108 is formed on the resistance change material layer 3107 in a cup shape. The conductive layer 3108 may be made of a metal, a silicide, an oxide, a nitride, an impurity doped silicon, or the like, as a material having conductivity, and according to the exemplary embodiment of the present invention, a metal material may be used as the conductive layer.

A selection device function layer 3109 is formed on the conductive layer 3108 in a cup shape. The selection device function layer 3109 is made of an insulating material controlling a passing current amount depending on a magnitude or polarity of a supplied voltage, for example, the silicon nitride or the high dielectric insulating material such as alumina. Further, when the insulating layer made of a material having a large difference in a dielectric constant is stacked as a multi-layer, the selection device function layer 3109 may show a larger effect.

The vertical electrode 3106 is formed by filling the opening with the conductive material while contacting the selection device function layer 3109. The plurality of vertical electrodes 3106 are electrically connected to each other through bit lines 3110 which are formed thereon.

Referring to FIG. 33, the resistance change material layer 3107 is formed between a horizontal electrode 3104c and the vertical electrode 3106, and the thin film layer 3105 formed by the atomic layer deposition (ALD) of 5 monolayers or less is formed between the resistance change material layer 3107 and the horizontal electrode 3104c. Therefore, the thin film layer 3105 is provided with a fine gap like B and the resistance change material layer 3107 contacts the horizontal electrode 3104c through the formed gap. Therefore, a contact area between the resistance change material layer 3107 and the horizontal electrode 3104c is minimized.

The conductive layer 3108 and the selection device function layer 3109 are formed between the resistance change material layer 3107 and the vertical electrode 3106. This forms a 1D1R structure. However, in the case of the resistance change memory without the selection device, the conductive layer 3108 and the selection device function layer 3109 may be omitted. In this case, the resistance change material layer 3107 directly contacts the vertical electrode 3106.

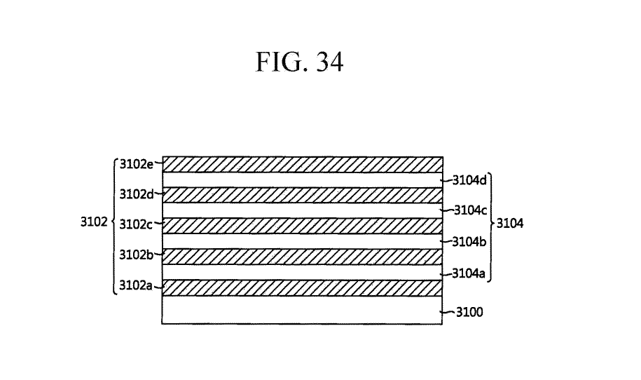

FIGS. 34 to 40 are process cross-sectional views for describing a method for manufacturing a vertically stacked resistance change memory device according to an exemplary embodiment of the present invention.

To manufacture the vertically stacked resistance change memory device according to the exemplary embodiment of the present invention, first, as illustrated in FIG. 34, the inter-layer insulating layer 3102 and the conductive layer 3104 are repeatedly stacked on the substrate 3100 in a vertical direction. The inter-layer insulating layers 3102 and the conductive layers 3104 may be formed by the chemical vapor deposition process. The conductive layer 3104 may be made of Pt, Ti, TiN, TaN, or W. Further, the inter-layer insulating layer 3102 may be formed of the silicon oxide layer, the silicon nitride layer, or the silicon oxynitride layer.

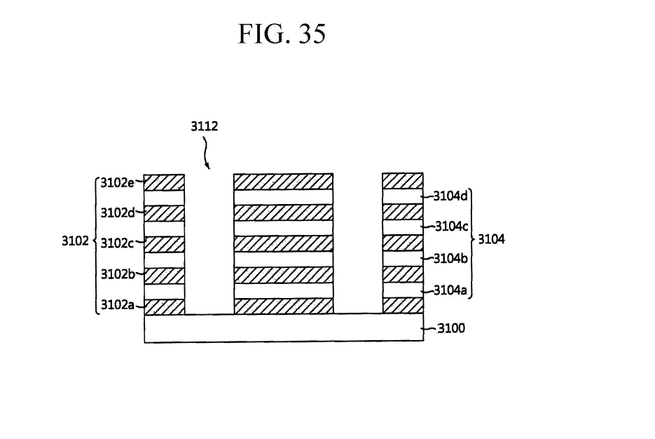

Referring to FIG. 35, the first photoresist pattern (not illustrated) is formed on the inter-layer insulating layer 3102e which is disposed on the top portion, and first openings 3112 are formed by sequentially etching the inter-layer insulating layers 3102a to 3102e and the conductive layers 3104a to 3104d using the first photoresist pattern as the etch mask. In this case, a surface of the substrate 3100 needs to be exposed on a bottom surface of the first opening 3112. Therefore, the horizontal electrode 3104 and the inter-layer insulation layer 3102 are formed.

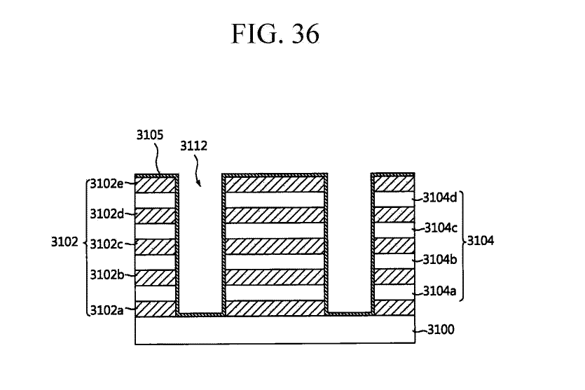

Referring to FIG. 36, the thin film layer 3105 is formed on the inter-layer insulating layer 3102e which is disposed on the top portion and along inner walls of the first openings 3112. The thin film layer 3105 may be formed of the silicon oxide layer, the silicon nitride layer, or the silicon oxynitride layer as an insulating layer of 5 monolayers or less formed by the atomic layer deposition (ALD). Therefore, the thin film layer 3105 has a fine gap.

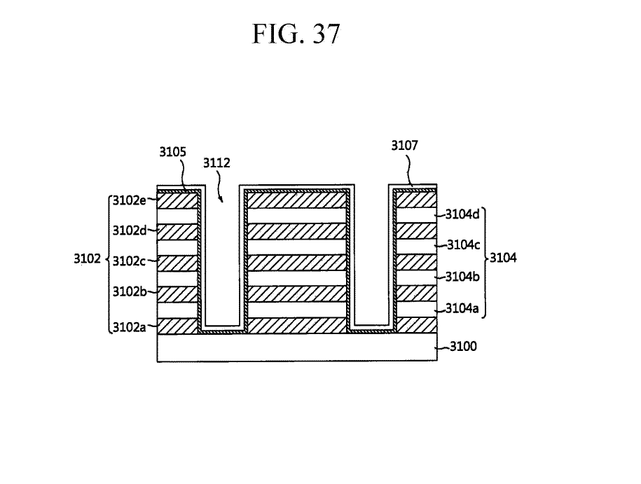

Referring to FIG. 37, the resistance change material layer 3107 is formed on the thin film layer 3105. The resistance change material layer 3107 may be made of a transition metal oxide, a phase change material, a perovskite material, and the like as a material in which the low resistance state and the high resistance state may be repeatedly changed depending on the applied voltage. According to the exemplary embodiment of the present invention, the resistance change material layer 3107 may be the oxygen ion mobile type or the metal ion mobile type which is operated at the low switching voltage. The resistance change material layer 3107 may be deposited by the physical vapor deposition or the chemical vapor deposition. For example, the resistance change material layer 3107 may be deposited by the sputtering method, in detail, the reactive sputtering method.

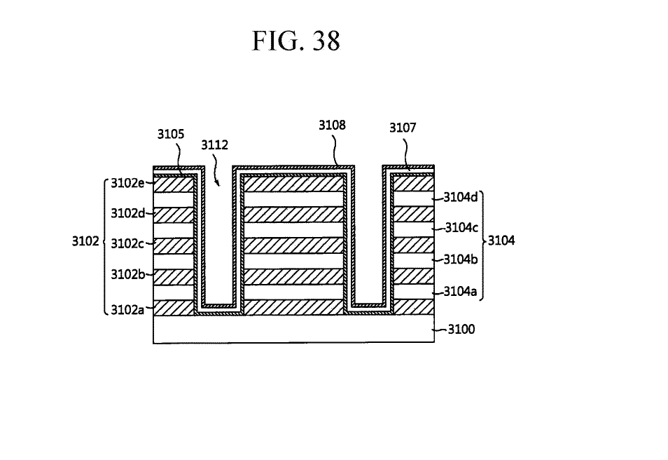

Referring to FIG. 38, the conductive layer 3108 is formed on the resistance change material layer 3107. The conductive layer 3108 may be made of a metal, a silicide, an oxide, a nitride, an impurity doped silicon, or the like, as a material having conductivity, and according to the exemplary embodiment of the present invention, a metal material may be used as the conductive layer. The conductive layer 3108 may be formed by the physical vapor deposition or the chemical vapor deposition. For example, the conductive layer 3108 may be formed by the sputtering method, in detail, the reactive sputtering method.

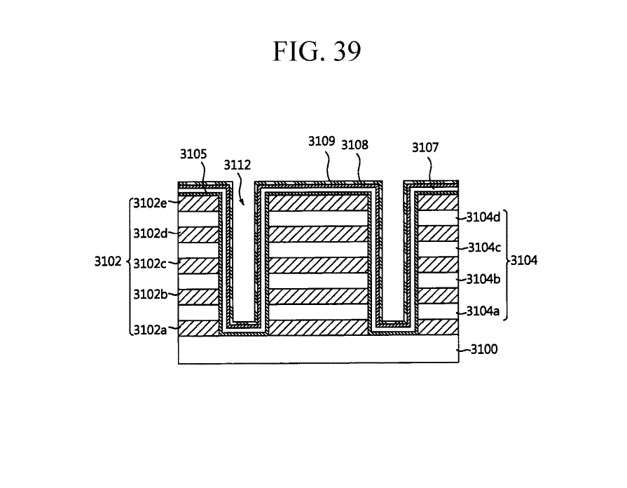

Referring to FIG. 39, the selection device function layer 3109 is formed on the conductive layer 3108. The selection device function layer 3109 is made of an insulating material controlling a passing current amount depending on a magnitude or polarity of supplied voltage, for example, the silicon nitride or the high dielectric insulating material such as alumina. Further, when the insulating layer made of a material having a large difference in a dielectric constant is stacked as a multi-layer, the selection device function layer 3109 may show a larger effect. The selection device function layer 3109 may be formed by chemical vapor deposition.

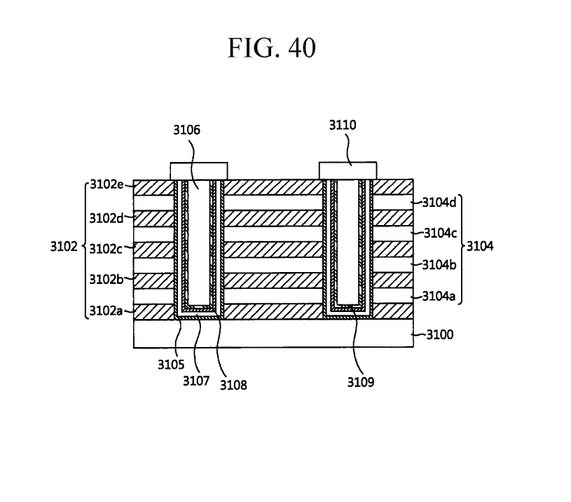

Referring to FIG. 40, except for the thin film layer 3105, the resistance change material layer 3107, the conductive layer 3108, and the selection device function layer 3109 which are formed within the first opening 3112, the thin film layer 3105, the resistance change material layer 3107, the conductive layer 3108, and the selection device function layer 3109 which are formed on the inter-layer insulating layer 3102e disposed on the top portion are removed. Further, the selection device function layer 3109 within the first opening 3112 is filled with the conductive material for forming the vertical electrode. To fill the inside of the first opening 3112 with the conductive material without a void, it is preferable to perform deposition using a material having good step coverage characteristics. For example, the conductive material may be Pt, Ti, TiN, TaN, W, etc. Therefore, the vertical electrode 3106 is formed.

Further, the conductive layer (not illustrated) is formed on the vertical electrodes 3106 and the inter-layer insulating layer 3102e which is disposed on the top portion. Next, the bit lines 3110 through which the upper portions of the vertical electrodes 3106 are connected to each other are formed by patterning the conductive layer using the photolithography process.

As described above, according to the exemplary embodiment of the present invention, the thin film layer is formed between the resistance change material layer and the horizontal electrode using atomic layer deposition (ALD) to bring the resistance change material layer into contact with the horizontal electrode through the fine gap formed in the thin film layer, in the vertical resistance change memory in which the resistance change material layers are formed at the cross points at which the plurality of horizontal electrodes extending in the horizontal direction and stacked having the insulating layer therebetween and the vertical electrodes extending in the vertical direction meet each other. Therefore, according to the exemplary embodiment of the present invention, it is possible to stably operate the resistance change memory by minimizing the contact area between the resistance change material layer and the electrode.

The exemplary embodiment of the present invention describes the resistance change memory cell having the 1D1R structure. However, in the case of using the resistance change material without the selection device, only the resistance change material layer 3107 is formed on the thin film layer 3105 and then the vertical electrode 3106 may be directly formed. Further, even in the 1D1R structure, the conductive layer 3108 formed between the resistance change material layer 3107 and the selection device function layer 3109 may be omitted, if necessary.

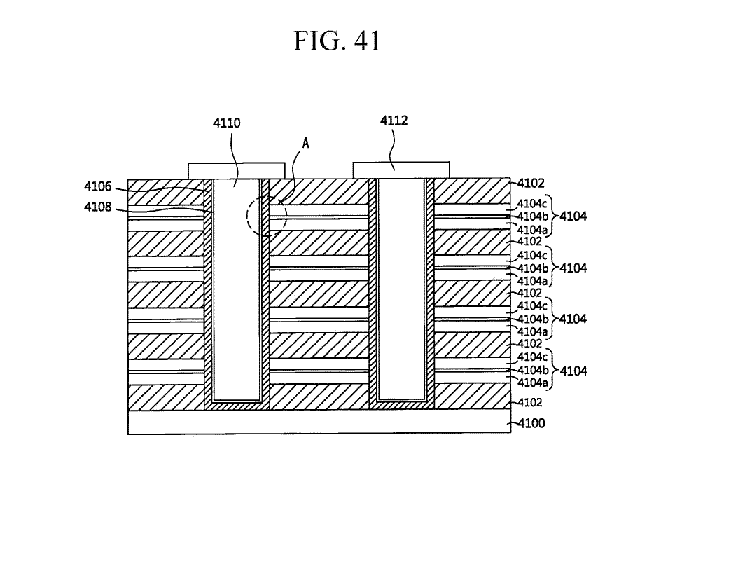

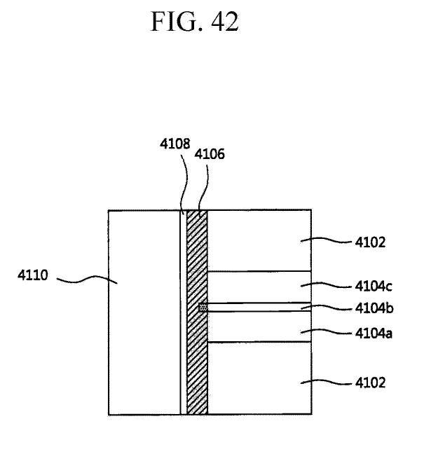

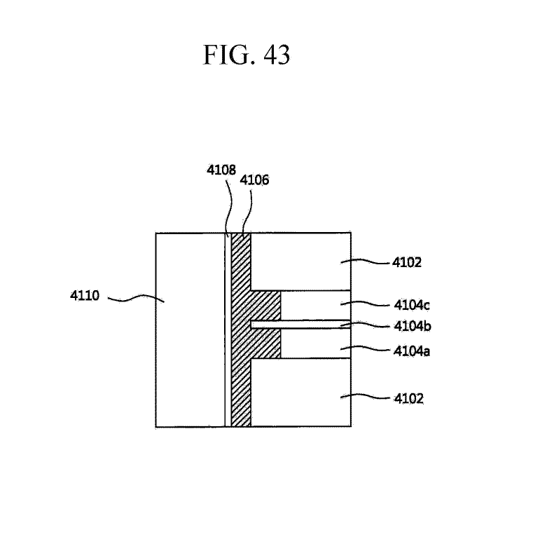

FIG. 41 is a cross-sectional view of the vertically stacked resistance change memory device according to the exemplary embodiment of the present invention, and FIGS. 42 and 43 are enlarged cross-sectional views of a portion A of FIG. 41 according to the exemplary embodiment of the present invention.

Referring to FIG. 41, a plurality of inter-layer insulating layers 4102 and a plurality of horizontal electrodes 4104 are alternately stacked on a substrate 4100. In this case, the horizontal electrode is made of a conductive material such as TiN, W, Cu, Ag, Ni, and Zr. According to the exemplary embodiment of the present invention, in forming the horizontal electrode, the horizontal electrode 4014 is configured of a conductive layer as a multi-layer including a first conductive layer 4104a/second conductive layer 4104b/third conductive layer 4104c using at least two conductive materials having different etch selectivities. For example, the horizontal electrode may be configured of the conductive layer as a multi-layer including W/TiN/W or W/Zr/W. For example, a thickness of the horizontal electrode 4104 may be 30 nm. In this case, a thickness of the second conductive layer 4104b formed in a middle portion may be 5 nm or less.

FIG. 42 illustrates the case in which the opening for forming the vertical electrode is formed and then a separate selection etching process for the horizontal electrode is not performed, and FIG. 43 illustrates the case in which the separate selection etching process is performed on the horizontal electrode.

Referring to FIGS. 42 and 43, the horizontal electrode 4104 is formed of a first conductive layer 4104a, a second conductive layer 4104b which is formed on the first conductive layer 4104a at a thickness of 5 nm or less and is made of a material having different etch selectivity from that of the first conductive layer 4104a, and a third conductive layer 4104c which is formed on the second conductive layer 4104b and is made of the same material as the first conductive layer 4104a. As illustrated in FIG. 42, the selection etching process is performed so that the vertical electrode penetrates through the horizontal electrodes stacked in order to form the opening for the vertical electrode, and the conductive layers 4104a to 4104c having a multi-layer structure configuring the horizontal electrode 4104 are made of different materials and thus the second conductive layer 4104b disposed on the intermediate layer has a more protruding form than the first and third conductive layers 4104a and 4104c. Therefore, the horizontal electrode 4104 has a lightening rod structure. FIG. 43 illustrates results obtained by performing the additional selection etching process on the horizontal electrode after the opening for the vertical electrode is formed. Therefore, the second conductive layer 4104b disposed on the intermediate layer has a more protruding form than the first and third conductive layers 4104a and 4104c. Therefore, the horizontal electrode 4104 has the lightening rod structure.

A plurality of vertical electrodes 4110 are formed to vertically penetrate through the inter-layer insulating layers 4102 and the horizontal electrodes 4104. Here, the vertical electrodes 4106 may be made of a metal conductor, for example, Pt, Ti, TiN, TaN, W, Cu, Ag, Ni, Zr, etc. Further, the inter-layer insulating layer 4102 may be formed of the silicon oxide layer, the silicon nitride layer, or the silicon oxynitride layer.

The resistance change material layer 4106 is formed in a cup shape to contact the inter-layer insulating layers 4102 and the horizontal electrodes 4104 along an inner wall of an opening in which the vertical electrode 4110 is formed. The resistance material layer 4106 may be formed to have a thickness of 5 nm by the atomic layer deposition (ALD) or the chemical vapor deposition (CVD).

The resistance change material layer 4106 may be a material in which the low resistance state and the high resistance state may be repeatedly changed depending on the applied voltage. For example, the resistance change material layer 4106 may include a transition metal oxide such as HfO, MnO, TiO, TaO, and NiO, a phase change material such as Pr_{0.7}Ca_{0.3}MnO₃ (PCMO), La_{0.7}Ca_{0.3}MnO₃ (LCMO), and Nb-doped SrTiO₃, a perovskite material, and the like.

A switching layer 4108 for the selection device may be selectively formed on the resistance change material layer 4106, if necessary. The switching layer 4108 may be configured of the conductive layer and the selection device function layer. The conductive layer may be made of a metal, a silicide, an oxide, a nitride, or an impurity doped silicon, and the like, as a material having conductivity. Further, the selection device function layer may be made of the insulating material controlling the passing current amount depending on the magnitude or polarity of a supplied voltage, for example, the silicon nitride or the high dielectric insulating material such as alumina.

The vertical electrodes 4110 are formed by filling the opening with the conductive material while contacting the switching layer 4108. The plurality of vertical electrodes 4110 are electrically connected to each other through bit lines 4112 which are formed thereon.

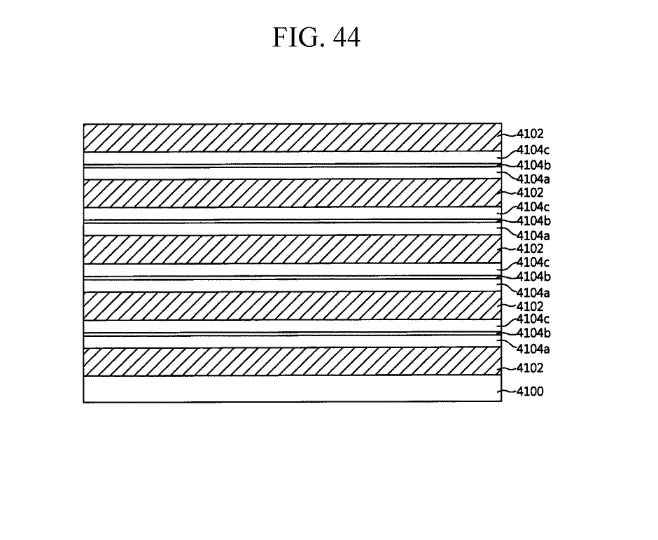

FIGS. 44 to 48 are process cross-sectional views for describing a method for manufacturing a vertically stacked resistance change memory device according to an exemplary embodiment of the present invention.

To manufacture the vertically stacked resistance change memory device according to the exemplary embodiment of the present invention, first, as illustrated in FIG. 44, the inter-layer insulating layer 4102 and the conductive layer 4104 are repeatedly stacked on the substrate 4100 in a vertical direction. In this case, the horizontal electrode may be made of a conductive material such as TiN, W, Cu, Ag, Ni, and Zr. According to the exemplary embodiment of the present invention, the horizontal electrode may be configured of a conductive layer of a multi-layer including the first conductive layer 4104a/second conductive layer 4104b/third conductive layer 4104c using at least two conductive materials having different etch selectivities. For example, the horizontal electrode may be configured of the conductive layer as a multi-layer such as W/TiN/W or W/Zr/W. The thickness of the horizontal electrode 4104 may be 30 nm. In this case, the thickness of the second conductive layer 4104b formed in a middle portion may be 5 nm or less.

The inter-layer insulating layers 4102 and the conductive layers 4104 may be formed by sputtering. Further, the inter-layer insulating layer 4102 may have a thickness of 30 nm and may be the silicon oxide layer, the silicon nitride layer, or the silicon oxynitride layer.

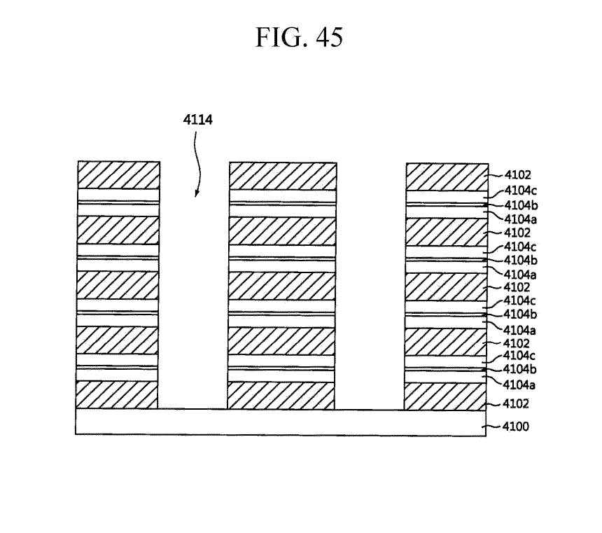

Referring to FIG. 45, the first photoresist pattern (not illustrated) is formed on the inter-layer insulating layer 4102 which is disposed on the top portion, and first openings 4114 are formed by sequentially etching the inter-layer insulating layers 4102 and the conductive layers 4014 using the first photoresist pattern as the etch mask. A surface of the substrate 4100 needs to be exposed on the bottom of the first opening 4114. Further, the first openings 4114 have a width of 30 nm and may be formed to be spaced apart from each other by 30 nm. Therefore, the horizontal electrode 4104 and the inter-layer insulation layer 4102 are formed. After the first opening 4114 is formed, as described with reference to FIG. 43, the additional selection etching process may be performed on the horizontal electrode.

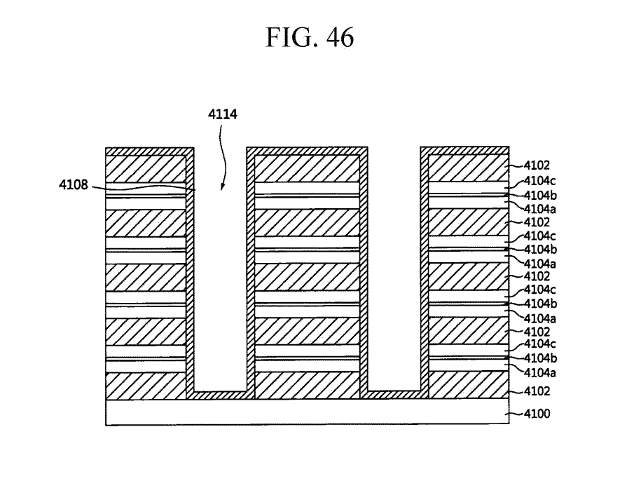

Referring to FIG. 46, the resistance change material layer 4106 is formed on the inter-layer insulating layer 4102 which is disposed on the top portion and along inner walls of the first openings 4114. The resistance change material layer 4106 may be made of a transition metal oxide, a phase change material, a perovskite material, and the like as a material in which the low resistance state and the high resistance state may be repeatedly changed depending on the applied voltage. The resistance change material layer 4106 may be deposited by the atomic layer deposition (ALD), the physical vapor deposition, or the chemical vapor deposition, and is formed to have a thickness of 5 nm.

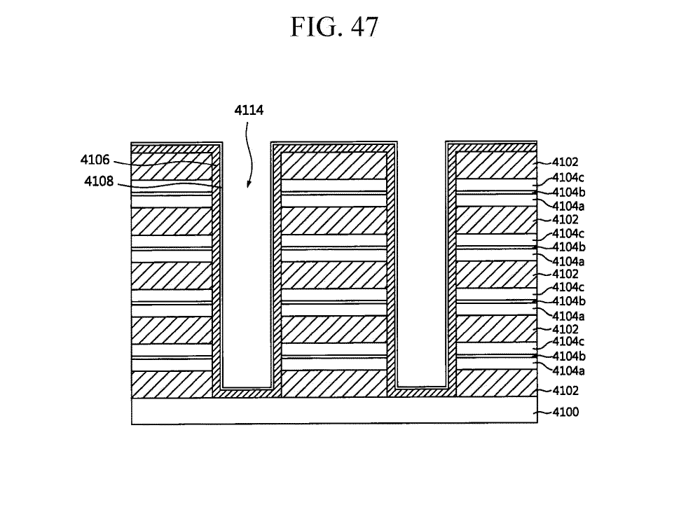

Referring to FIG. 47, the switching layer 4108 may be selectively formed on the resistance change material layer 4106, if necessary. The switching layer 4108 may be configured of the conductive layer and the selection device function layer. Further, the conductive layer may be made of a metal, a silicide, an oxide, a nitride, or an impurity doped silicon, and the like, as a material having conductivity. In addition, the selection device function layer 4109 is made of the insulating material controlling the passing current amount depending on the magnitude or polarity of a supplied voltage, for example, the silicon nitride or the high dielectric insulating material such as alumina.

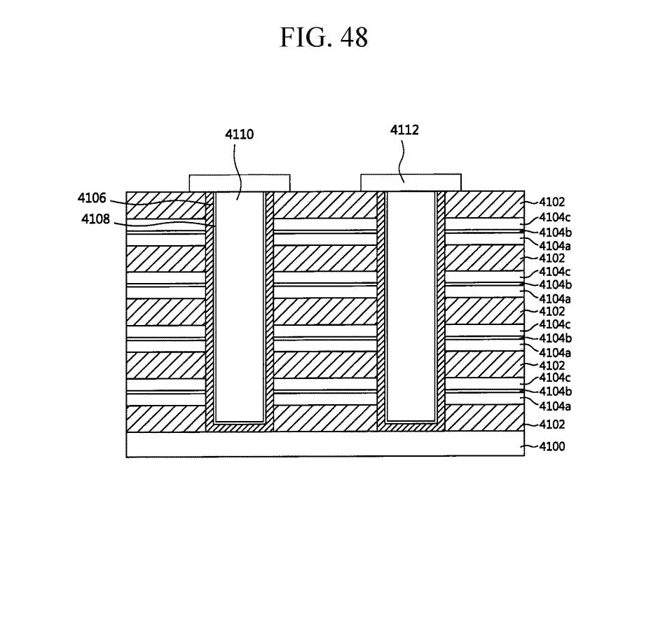

Referring to FIG. 48, except for the resistance change material layer 4106 and the switching layer 4108 which are formed within the first opening 4114, the resistance change material layer 4106 and the switching layer 4108 which are formed on the inter-layer insulating layer 4102 disposed on the top portion are removed. Further, the conductive material for the vertical electrode is filled on the switching layer 4108 within the first opening 4114. To fill the inside of the first opening 4114 with the conductive material without a void, it is preferable to perform deposition using a material having good step coverage characteristics. For example, the conductive material may be Pt, Ti, TiN, TaN, W, etc. Therefore, the vertical electrode 4110 is formed.

Further, the conductive layer (not illustrated) is formed on the vertical electrodes 4110 and the inter-layer insulating layer 4102 which is disposed on the top portion. Next, bit lines 4112 through which the upper portions of the vertical electrodes 4110 are connected to each other are formed by patterning the conductive layer using the photolithography process.

As described above, according to the exemplary embodiments of the present invention, it is possible to configure the horizontal electrode in the multi-layer using the conductive materials having different etch selectivities to have the lightening rod structure, in the vertical resistance change memory in which the resistance change material layers are formed at the cross points at which the plurality of horizontal electrodes extending in the horizontal direction and stacked having the insulating layer therebetween and the vertical electrodes extending in a vertical direction meet each other. Thereby, the switching uniformity of the resistance change material layer may be improved, thereby stably operating the resistance change memory.

The exemplary embodiment of the present invention describes the resistance change memory cell having the 1D1R structure. However, when the resistance change material without the selection device is used, the resistance change memory cell may be formed only of the resistance change material layer 4106 without the switching layer.

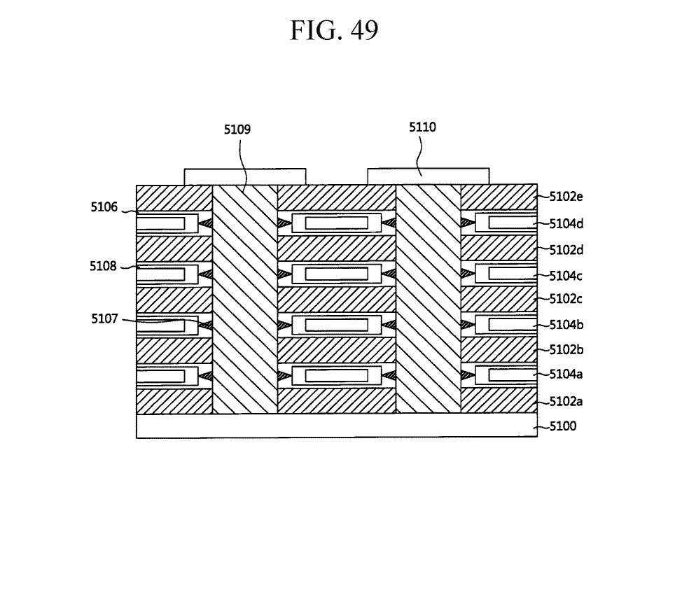

FIG. 49 is a cross-sectional view of a vertically stacked resistance change memory device according to an exemplary embodiment of the present invention.

Referring to FIG. 49, insulating layers 5102a to 5102e and horizontal electrodes 5104a to 5104d are alternately stacked on a substrate 5100, and a plurality of vertical electrodes 5109 are formed to vertically penetrate through the insulating layers 5102a to 5102e and the horizontal electrodes 5104a to 5104d. In this configuration, the horizontal electrodes 5104a to 5104d and the vertical electrodes 5109 may be made of a metal conductor, for example, Pt, Ti, TiN, TaN, and W. Further, the insulating layers 5102a to 5102e may be formed of a silicon oxide layer, a silicon nitride layer, or a silicon oxynitride layer. The plurality of vertical electrodes 5109 are electrically connected to each other through bit lines 5110 which are formed thereon.

The resistance change material layers are formed at points at which the vertical electrodes 5109 and the horizontal electrodes 5104a to 5104d cross each other. The resistance change material layer is configured of a first resistance change material layer 5106 and a second resistance change material layer 5108 which is made of a material different from that of the first resistance change material layer 5106. The first resistance change material layer 5106 and the second resistance change material layer 5108 are made of a transition metal oxide such as HfO₂, MnO₂, TiO₂, TaO₂, and NiO₂. The first resistance change material layer 5106 is formed on a side wall of the vertical electrode 5109 and the insulating layers 5102a to 5102e.

A metal ion filament 5107 made of metal ions such as copper (Cu) or silver (Ag) ions is formed within the first resistance change material layer 5106. After copper or silver is deposited on the first resistance change material layer 5106, the metal ion filament 5107 may be formed by heat treatment at a temperature of 400° C. for a predetermined time. The second resistance change material layer 5108 made of a different transition metal oxide from the first resistance change material layer 5106 is formed on the first resistance change material layer 5106 on which the metal ion filament 5107 is formed. The horizontal electrodes 5104a to 5104d which extend in the horizontal direction are formed on the second resistance change material layer 5108.

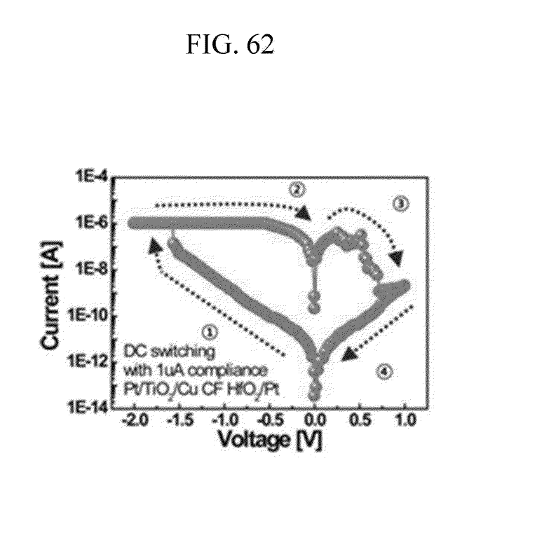

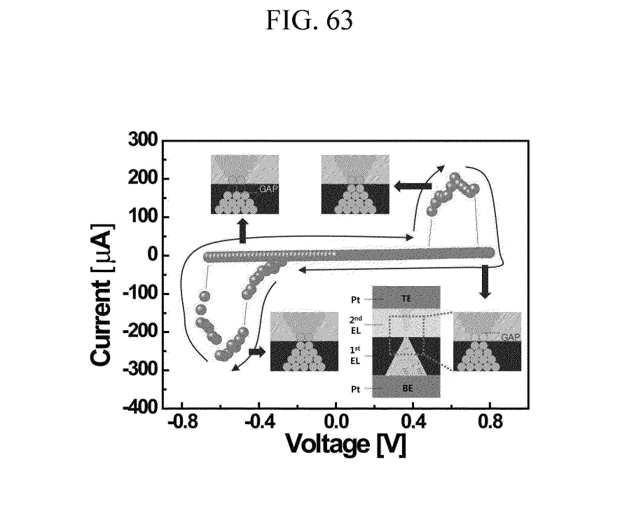

FIGS. 62 and 63 are graphs illustrating a current-voltage characteristic of the resistance change memory device according to the exemplary embodiment of the present invention.

The graphs illustrated in FIGS. 62 and 63 represents results of an example in which platinum (Pt) is used as the vertical electrode 5109, HfO₂ is used as the first resistance change material layer 5106, copper (Cu) is used as the metal ion filament 5107, TiO₂ is used as the second resistance change material layer 5108, and platinum (Pt) is used as the horizontal electrode 5104.

As illustrated in FIGS. 62 and 63, when an amount of metal ions within the resistance change material layer is minimized in an atomic unit, just as sand flows no more due to the limited amount of sand in a sandglass, a current flows no more at a specific voltage/time condition or more and thus current-voltage characteristics similar to those of the device with the selection device may be implemented. That is, when the filament is formed within the first resistance change material layer by minimizing the amount of copper (Cu) as a scale of a unit of the atomic layer, the first resistance change material layer shows the current-voltage characteristics as illustrated in FIGS. 62 and 63. Therefore, the first resistance change material layer without the separate selection device shows the current-voltage characteristics like the first resistance change material layer with the selection device and thus serves as the selection device.

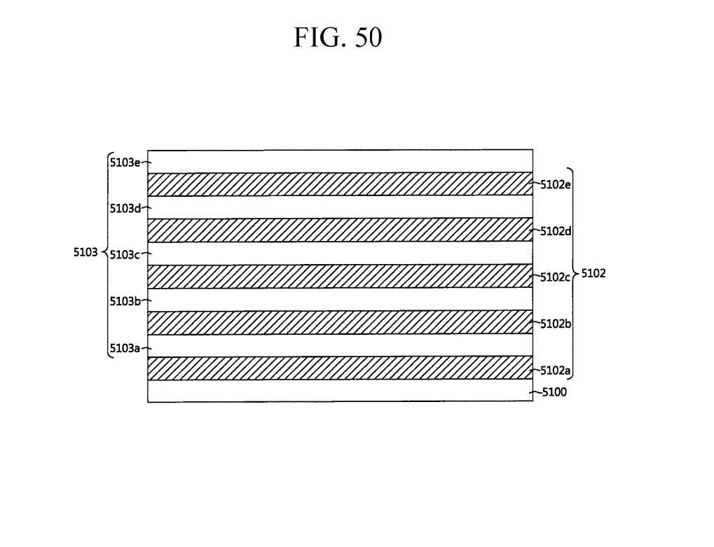

FIGS. 50 to 61 are process cross-sectional views for describing the method for manufacturing a vertically stacked resistance change memory device according to the exemplary embodiment of the present invention.

To manufacture the vertically stacked resistance change memory device according to the exemplary embodiment of the present invention, first, as illustrated in FIG. 50, an inter-layer insulating layer 5102 and a sacrificial layer 5103 are repeatedly stacked on the substrate 5100 in a vertical direction. The inter-layer insulating layers 5102 and the sacrificial layers 5103 may be formed by a chemical vapor deposition process.

According to the exemplary embodiment of the present invention, an inter-layer insulating layer 5102a may be disposed on the bottom portion of the repeatedly stacked structure. In this case, the exemplary embodiment of the present invention describes that a sacrificial layer 5103e is disposed on the top portion, but the inter-layer insulating layer 5102e may be disposed on the top portion.

The sacrificial layers 5103 are removed in subsequent processes and thus define a portion at which the resistance change material layer is formed and the horizontal electrode is formed. The sacrificial layers 5103 need to be made of a material having different etch selectivity from the inter-layer insulating layers 5102. Further, the sacrificial layers 5103 need to be made of a material which may be easily removed by a wet etching process. Preferably, the sacrificial layers 5103 may be made of a silicon oxide and the inter-layer insulating layers 5102 may be made of a silicon nitride. Hereinafter, the case in which the sacrificial layer 5103 is formed of a silicon oxide layer and the inter-layer insulating layer 5102 is formed of a silicon nitride layer will be described.

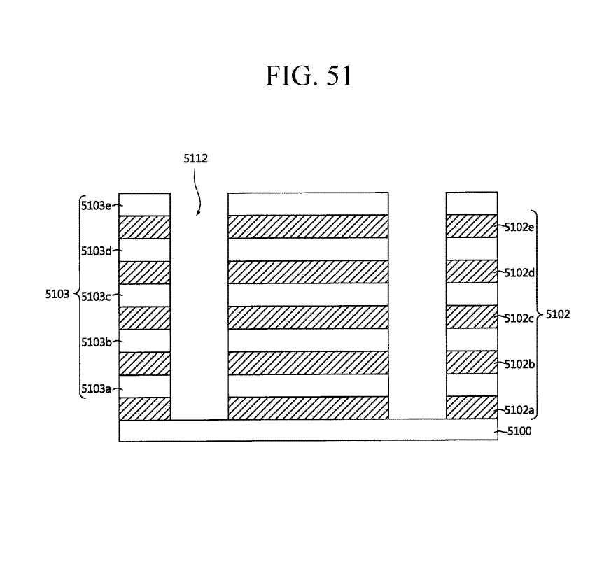

Referring to FIG. 51, a first photoresist pattern (not illustrated) is formed on the silicon oxide layer 5103e which is disposed on the top portion, and first openings 5112 are formed by sequentially etching the silicon oxide layers 5103 and the silicon nitride layers 5102 using the first photoresist pattern as an etch mask. In this case, a surface of the substrate 5100 needs to be exposed at a bottom surface of the first opening 5112.

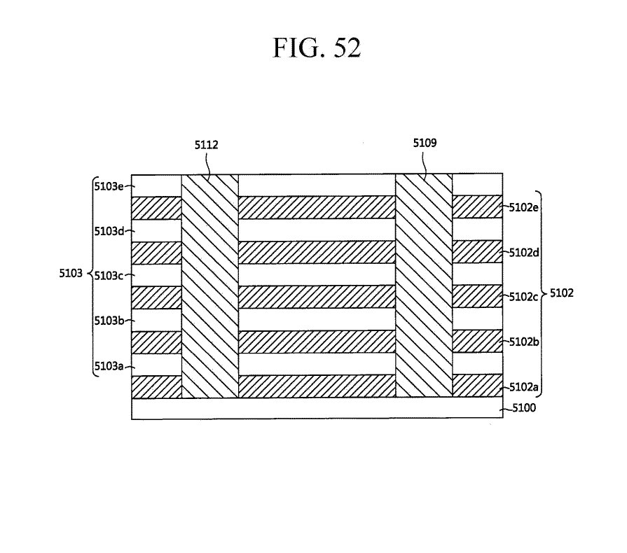

Referring to FIG. 52, the vertical electrode 5109 is formed by filling insides of the first openings 5112 with the conductive layer for the forming vertical electrode. Here, the conductive layer may be made of Pt, Ti, TiN, TaN, W, etc.

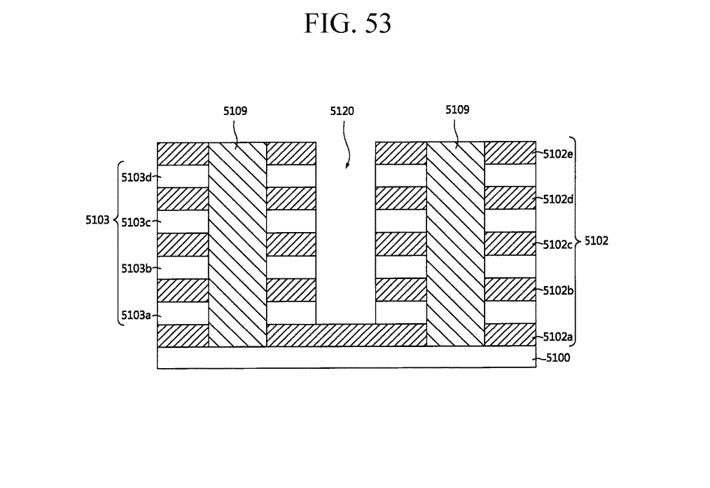

Referring to FIG. 53, after the vertical electrode 5109 is formed by filling the inside of the first opening 5112 with the conductive layer, the silicon oxide layer 5103e is removed by a polishing process so as to expose the silicon nitride layer 5102e. Further, the second photoresist pattern (not illustrated) which selectively exposes a portion of the stacked structure between the vertical electrodes 5109 is formed on the stacked structure. In addition, second openings 5120 are formed by etching the stacked structure using the second photoresist pattern as the etch mask. An upper surface of the first silicon nitride layer 5102a which is a bottom layer of the stacked structure needs to be exposed at a bottom surface of each of the second openings 5120. In this case, the second openings 5120 are provided to prepare a space through which a wet etchant is permeated into the silicon oxide layers of each layer so as to remove the silicon oxide layer patterns 5103a to 5103d.

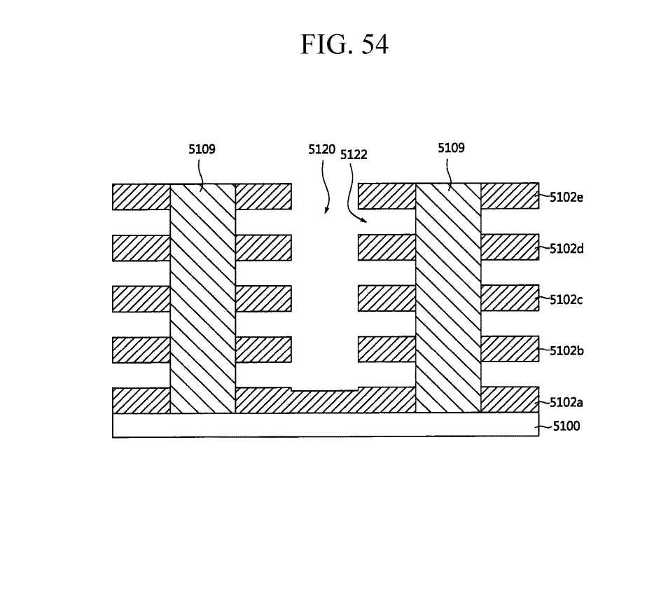

Referring to FIG. 54, first to fourth silicon oxide layer patterns 5103a to 5103d which are exposed on side walls of the second openings 5120 are selectively removed. The first to fourth silicon oxide layer patterns 5103a to 5103d are removed by the wet etching process. In detail, the first to fourth silicon oxide layer patterns 5103a to 5103d are removed using a hydrofluoric acid aqueous solution. When the above process is performed, the first to fifth silicon nitride layer patterns 5102a to 5102e remain on the side wall of the vertical electrode 5109 at predetermined intervals. Further, concave portions 5122 are generated at a portion at which the first to fourth silicon oxide layer patterns 5103a to 5103d are removed from the side walls of the second openings 5120. In this case, the concave portions 5122 of respective layers communicate with each other, and the side wall of the vertical electrode 5109 is exposed by the concave portion 5122. The side wall of the vertical electrode 5109 exposed by the concave portion 5122 is a portion at which the resistance change material layer is formed.

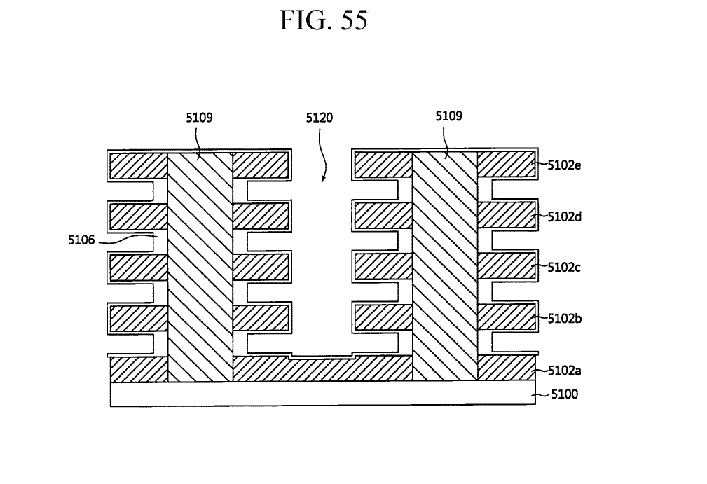

Referring to FIG. 55, the first resistance change material layers 5106 are formed on the side wall of the vertical electrode 5109 exposed by the concave portion 5122 and the silicon nitride layer patterns (insulating layers) 5102a to 5102e within the concave portion. The first resistance change material layer 5106 may be made of a transition metal oxide such as HfO₂, MnO₂, TiO₂, TaO₂, and NiO₂. The first resistance change material layer 5106 may be formed by atomic layer deposition (ALD).

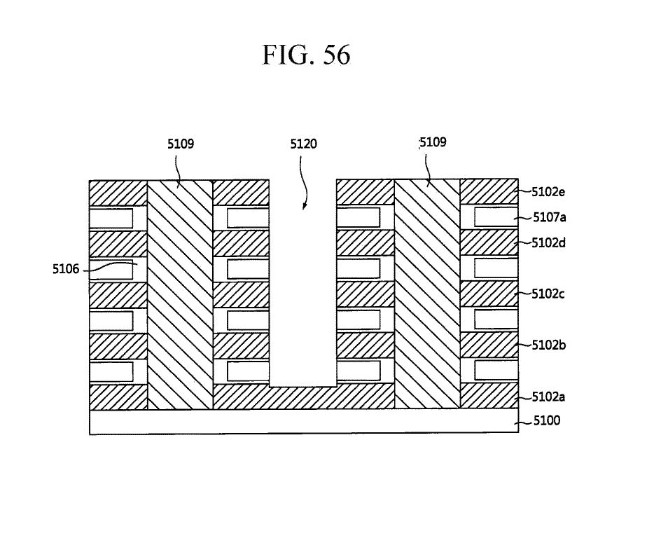

Referring to FIG. 56, a metal material 5107a such as copper or silver is deposited on the first resistance change material layer 5106 to completely fill the inside of the concave portion 5122. In this case, the metal material 5107a such as copper or silver may be deposited by the atomic deposition (ALD) or the sputtering method. Although the exemplary embodiment of the present invention describes that the deposition is performed to completely fill the concave portion with copper or silver, a required amount of metal is about 1 to 2 atomic layers and therefore the deposition may be made without completely filling the inside of the concave portion.

The metal ion filament 5107 made of a copper or silver material is formed within the first resistance change material layer 5106 by depositing the metal material 5107a such as copper or silver within the concave portion on the first resistance change material layer 5106 and then heat-treating the metal material 5107a at a temperature of 400° C. or less for several seconds to several minutes.

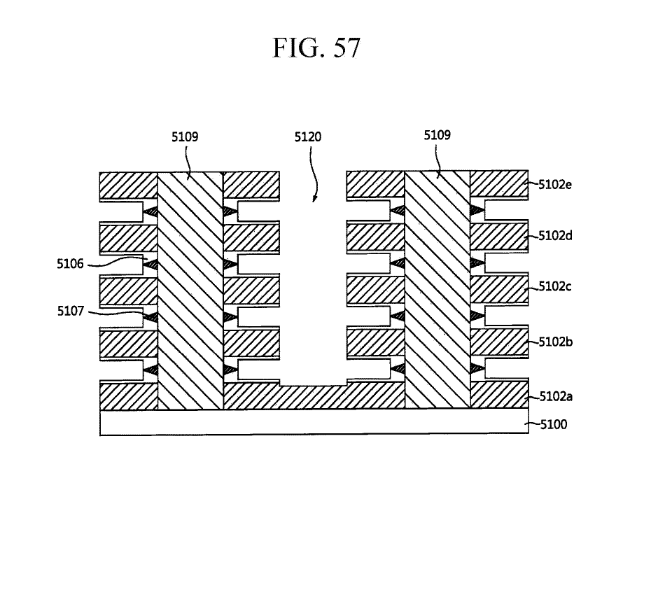

Referring to FIG. 57, after the metal ion filament 5107 is formed within the first resistance change material layer 5106, the metal material such as copper or silver which remains within the concave portion is completely removed by the wet etching process. Therefore, only the first resistance change material layer 5106 on which the metal ion filament 5107 is formed remains in the concave portion.

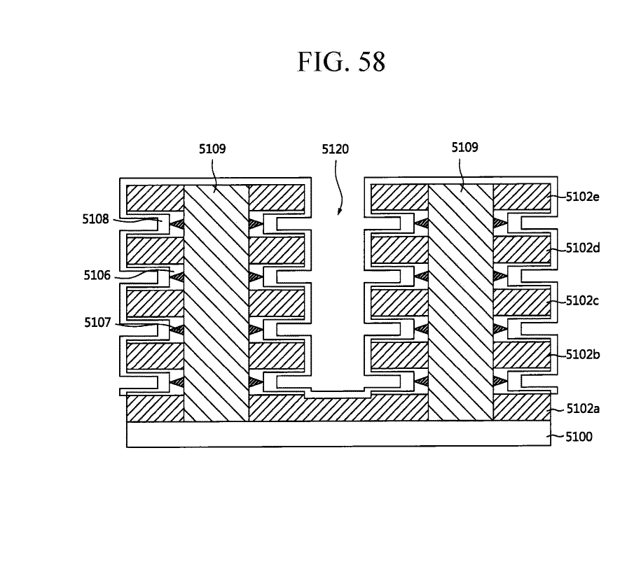

Referring to FIG. 58, the second resistance change material layer 5108 made of a different transition metal oxide from the first resistance change material layer 5106 is formed on the first resistance change material layer 5106 on which the metal ion filament 5107 is formed. Here, the second resistance change material layer 5108 may be made of a transition metal oxide having different metal ion diffusion from the first resistance change material layer. The second resistance change material layer 5108 is formed on the first resistance change material layer 5106 by the atomic layer deposition method (ALD).

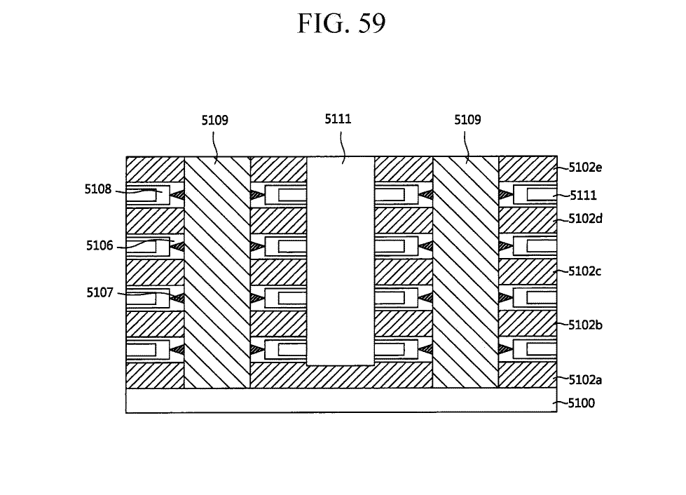

Referring to FIG. 59, a conductive layer 5111 is formed within the concave portion on the second resistance change material layer 5108 and the second opening 5102. The conductive layer 5111 is provided as the horizontal electrode pattern by subsequent processes. To fill the insides of the second opening 5120 and the concave portion 5122 with the conductive layer 5111 without a void, it is preferable to perform deposition using a material having good step coverage characteristics. For example, the conductive layer 5111 may be made of Pt, Ti, TiN, TaN, W, etc.

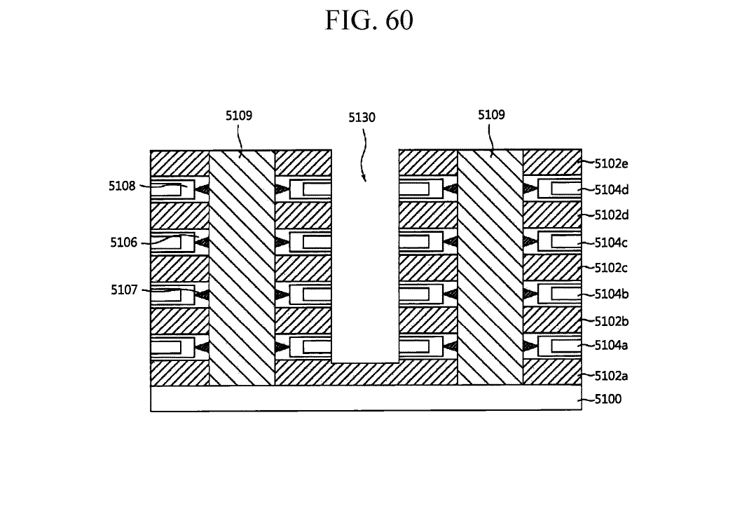

Referring to FIG. 60, a third photoresist pattern (not illustrated) which selectively exposes an upper surface of the conductive layer 5111 which is formed inside the second opening 5120 is formed on the upper surface of the stacked structure. That is, the third photoresist pattern has a shape through which the same portion as the second opening 5120 or a wider portion than the second opening 5120 are exposed. Further, the conductive layer 5111 exposed using the third photoresist pattern as the etch mask undergoes anisotropic etching to form third openings 5130 through which the conductive layer patterns 5104a to 5104d of each layer are separated from each other in the vertical direction. The first silicon nitride layer pattern 5102a may be exposed on the bottom surface of the third openings 5130. The first to fourth horizontal electrodes 5104a to 5104e are formed between the first to fifth silicon nitride layer patterns 5102a to 5102e by the etch process. In this case, the horizontal electrodes 5104a to 5104d which are formed on the same layer are electrically connected to each other. However, the horizontal electrodes 5104a to 5104e which are formed on different layers are insulated from each other.

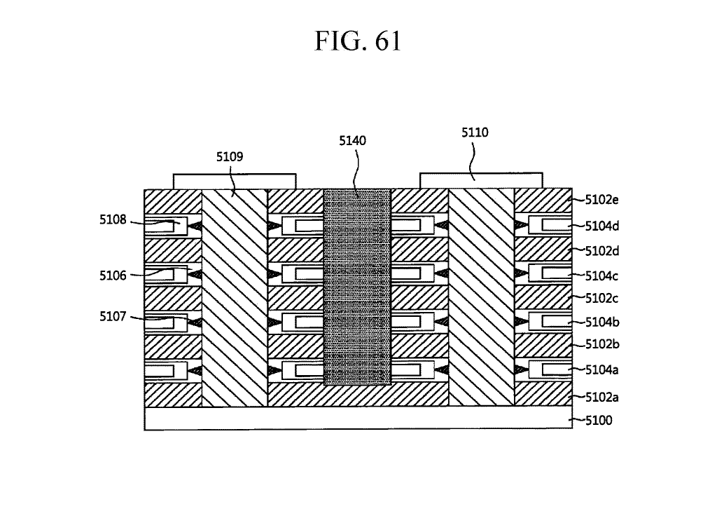

Referring to FIG. 61, the inside of the third opening 130 may be filled with an insulating material 5140. Alternatively, the additional vertical electrode may be formed by filling the inside of the third opening 5103 with the conductive layer for the vertical electrode. Further, the conductive layer (not illustrated) is formed on the vertical electrodes 5109 and the fifth silicon nitride layer patterns 5102e. Next, the bit lines 5110 through which the upper portions of the vertical electrode patterns 5109 are connected to each other are formed by patterning the conductive layer using the photolithography process.

Claims of the present invention are not limited to specific embodiments and therefore those skilled in the art may variously replace, modify, and change the present invention without departing from the scope of the present invention. Accordingly, the embodiments disclosed in the present invention and the accompanying drawings are used not to limit but to describe the spirit of the present invention. The scope of the present invention is not limited to the embodiments and the accompanying drawings. The protection scope of the present invention must be analyzed by the appended claims, and it should be analyzed such that all spirits within a scope equivalent thereto are included in the scope of the present invention.

1. A vertically stacked resistance change memory device, comprising:
a plurality of horizontal electrodes configured to be stacked at a predetermined interval from each other and extended in a horizontal direction;
inter-layer insulating layers configured to each be formed between the plurality of horizontal electrodes;
a plurality of vertical electrodes configured to have cross points with the horizontal electrodes by penetrating through the plurality of stacked horizontal electrodes and the inter-layer insulating layers in a vertical direction; and
a metal oxide layer configured to have a U-shaped section in a form enclosing the horizontal electrode between the inter-layer insulating layer and the horizontal electrode and to make an oxygen composition ratio of a surface contacting the vertical electrode be higher than that of a surface contacting the horizontal electrode by performing oxygen treatment on the surface contacting the vertical electrode to have threshold switching characteristics and memory switching characteristics.

2. The vertically stacked resistance change memory device of claim 1, wherein
the metal oxide layer
includes the same metal oxide, a portion at which the oxygen composition ratio of the surface contacting the vertical electrode is high has the memory switching characteristics, and the surface contacting the horizontal electrode has the threshold switching characteristics.

3. The vertically stacked resistance change memory device of claim 2, wherein
the metal oxide layer is made of any one of FeOₓ, VOₓ, TiOₓ, and NbOₓ.

4. The vertically stacked resistance change memory device of claim 1, wherein
the horizontal electrode and the vertical electrode are formed of a metal conductor.

5. The vertically stacked resistance change memory device of claim 1, wherein
the inter-layer insulating layer is made of a silicon nitride.

6. A method for manufacturing a vertically stacked resistance change memory device having a hybrid switching layer, the method comprising:
(a) alternately stacking an inter-layer insulating layer and a sacrificial layer on a substrate;
(b) forming first openings spaced from each other at a predetermined interval, while penetrating through the inter-layer insulating layer and the sacrificial layer in a vertical direction and forming pillar parts by filling the first openings with a removable material;
(c) forming concave portions between the inter-layer insulating layers by forming a plurality of second openings between the pillar parts and then removing the sacrificial layer;
(d) forming a metal oxide layer on the pillar part and the inter-layer insulating layer which are exposed by the concave portion;
(e) forming horizontal electrodes by embedding a conductive material on the metal oxide layer formed inside the concave portion;
(f) forming a third opening by removing the pillar part so as to expose a portion of the metal oxide layer;
(g) performing oxygen treatment on the metal oxide layer exposed through the third opening so as to have memory switching characteristics and threshold switching characteristics; and
(h) embedding a conductive material within a third opening to form vertical electrodes.

7. The method of claim 6, wherein
in the step (g), the metal oxide layer is made of the same metal oxide, a surface contacting the vertical electrode has a high oxygen composition ratio and thus has the memory switching characteristics, and a surface contacting the horizontal electrode has the threshold switching characteristics.

8. The method of claim 7, wherein
the metal oxide layer is made of any one of FeOₓ, VOₓ, TiOₓ, and NbOₓ.

9. The method of claim 7, wherein
the inter-layer insulating layer is made of a silicon nitride.

10. The method of claim 7, wherein
the sacrificial layer is made of a silicon oxide.

11. The method of claim 7, further comprising
forming the vertical electrodes, forming a conductive layer on the inter-layer insulating layer, and forming bit lines by patterning.
